(19) United States
(12) Patent Application Publication
(10) Pub. No.: US 2026/0339840 A1
(43) Pub. Date: Oct. 29, 2026

(54) MOLECULAR MEMORY, METHOD FOR MANUFACTURING MOLECULAR MEMORY, METHOD FOR DECODING MOLECULAR MEMORY, AND DEVICE FOR DECODING MOLECULAR MEMORY

(71) Applicant: OSAKA UNIVERSITY, Osaka (JP)

(72) Inventors: Masateru TANIGUCHI, Osaka (JP); Takahito OHSHIRO, Osaka (JP)

(21) Appl. No.: 19/107,557

(22) PCT Filed: Aug. 24, 2023
(86) PCT No.: PCT/JP2023/030588

§ 371 Date: Feb. 27, 2025

(30) Foreign Application Priority Data
Aug. 29, 2022 (JP) 2022-136341

(51) Int. Cl. G06F 12/06

(52) U.S. Cl. CPC G06F 12/06; G06F 2212/21

(57) ABSTRACT

An object is to provide a molecular memory. The object can be achieved by a molecular memory including: an address region; and a memory region connected to the address region, in which the address region and the memory region are constituted of molecules that generate tunnel current, the memory region is constituted of four or more types of molecules selected from a first molecule group, the address region is constituted of four or more types of molecules selected from a second molecule group, the molecules included in the first molecule group all are of different types from the types of the molecules included in the second molecule group or include the same type as and a different type from the types of the molecules included in the second molecule group, and thereby at least some of the molecules constituting the address region and the memory region differ in types.

### TECHNICAL FIELD

The present disclosure of the present application relates to a molecular memory, a production method of a molecular memory, a decoding method of a molecular memory, and a device for decoding a molecular memory.

### BACKGROUND ART

With the rapid development of the information society and AI, an explosive amount of data is being produced around the world. If quantum computers are put into practical use in the future, the increase in the amount of data produced will be explosively accelerated. However, about 70 to 80% of massively produced data are cold data that are rarely used after the production thereof. Since cold data are used in management of documents such as contracts, these cold data are required to be stored for a certain period or longer, and for the storage of such cold data, a large amount of electrical power and storage resource are used.

To solve the above problem, DNA memories that enable long term storage without needing electrical power have been developed. To acquire information stored in a DNA memory, it is necessary to read a DNA sequence. As a method of reading a DNA sequence, PCR methods are used in general. However, reading of a DNA sequence using a PCR method requires a pre-processing step such as a PCR before the reading. Further, while use of Adenosine (A), Guanosine (G), Cytidine (C), and Thymidine (T) constituting a DNA provides a storage density per base of 2 bits/nt, it is known that the storage density per base is limited to an information quantity in view of replication errors due to a PCR in practice, which is 1.57 bits/nt (see Patent Literature 1). Thus, Patent Literature 1 discloses that oligonucleotides are immobilized onto a substrate, oligonucleotides are labeled with labeled atoms that can be identified by imaging mass spectrometry or imaging X-ray photoelectron spectroscopy, and thereby analysis of sequences and reading of information are made possible without needing destruction, replication, or amplification.

Further, a method of measuring tunnel current occurring when DNA passes between nano-gap electrodes and then reading a DNA sequence based on a difference in conductance of DNA molecules is known as a method of reading DNA sequences (see Non-Patent Literature 1).

### CITATION LIST

### Patent Literature

Patent Literature 1: Japanese Patent Application Laid-Open No. 2019-132588

### Non-Patent Literature

Non-Patent Literature 1: Takahito Ohshiro et al., “Direct Analysis of Incorporation of an Anticancer Drug into DNA at Single-Molecule Resolution”, Scientific Reports, (2019) 9:3886 |https://doi.org/10.1038/s41598-019-40504-x

### SUMMARY OF INVENTION

### Technical Problem

The DNA reading method disclosed in Non-Patent Literature 1 can identify molecules having different electron states on a single molecular basis. However, the method disclosed in Non-Patent Literature 1 relates to reading of general DNA sequences. Desired molecular arrangement when molecules constituting a molecular memory is read on a molecule basis is not known.

The disclosure of the present application has been made in order to solve the above conventional problems. According to an intensive study made by the present inventors, it has been newly found that the capacity of a molecular memory can be increased by (1) forming an address region with molecules that generate tunnel current and a memory region connected to the address region and (2) differentiating types of at least some of the molecules constituting the address region and the memory region.

That is, an object of the disclosure of the present application is to provide a molecular memory suitable for reading on a molecule basis, a production method of a molecular memory, a decoding method of the molecular memory, and a device for decoding the molecular memory.

### Solution to Problem

The disclosure of the present application relates to a molecular memory, a production method of a molecular memory, a decoding method of a molecular memory, and a device for decoding a molecular memory illustrated below.
(1) A molecular memory comprising: an address region; and a memory region connected to the address region,
   wherein the address region and the memory region are constituted of molecules that generate tunnel current,
   wherein the memory region is constituted of four or more types of molecules selected from a first molecule group,
   wherein the address region is constituted of four or more types of molecules selected from a second molecule group,
   wherein the molecules included in the first molecule group
      all are of different types from the types of the molecules included in the second molecule group, or
      include the same type as and a different type from the types of the molecules included in the second molecule group, and
   wherein due to the molecules included in the first molecule group, at least some of the molecules constituting the address region and the memory region differ in types.
(2) The molecular memory according to (1) above, wherein when the first molecule group includes molecule of the same type as the molecules included in the second molecule group, the molecule of the same type included in the first molecule group and the second molecule group is not arranged neither at a terminal on the memory region side in the address region nor at a terminal on the address region side in the memory region.
(3) The molecular memory according to (1) above,
   wherein a molecule having the smallest conductance in the molecules included in the first molecule group is not arranged at a terminal of the memory region on the opposite side from the address region side, and
   wherein a molecule having the smallest conductance in the molecules included in the second molecule group is not arranged at a terminal of the address region on the opposite side from the memory region side.
(4) The molecular memory according to (1) above, wherein all the types of the molecules included in the first molecule group differ from the types of the molecules included in the second molecule group.
(5) The molecular memory according to (3) above, wherein all the types of the molecules included in the first molecule group differ from the types of the molecules included in the second molecule group.
(6) The molecular memory according to (4) above,
   wherein one of the first molecule group and the second molecule group includes four or more types of molecules selected from a group consisting of:

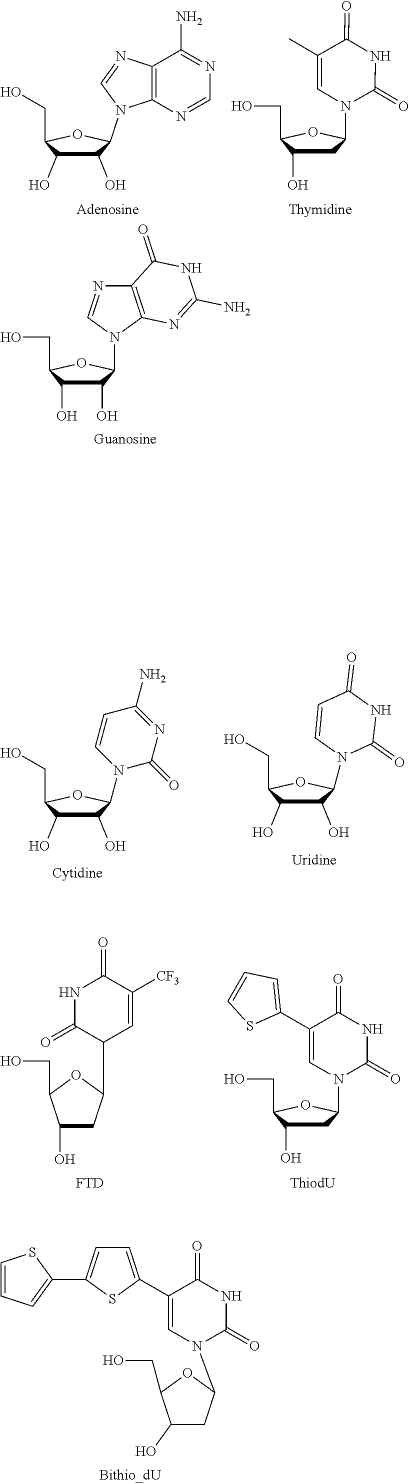

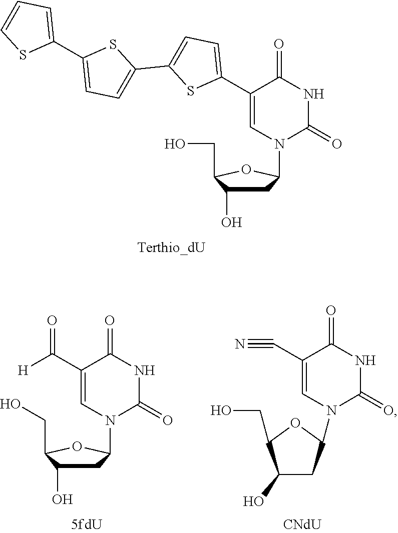

and
wherein the other of the first molecule group and the second molecule group includes four or more types of molecules selected from a group consisting of:

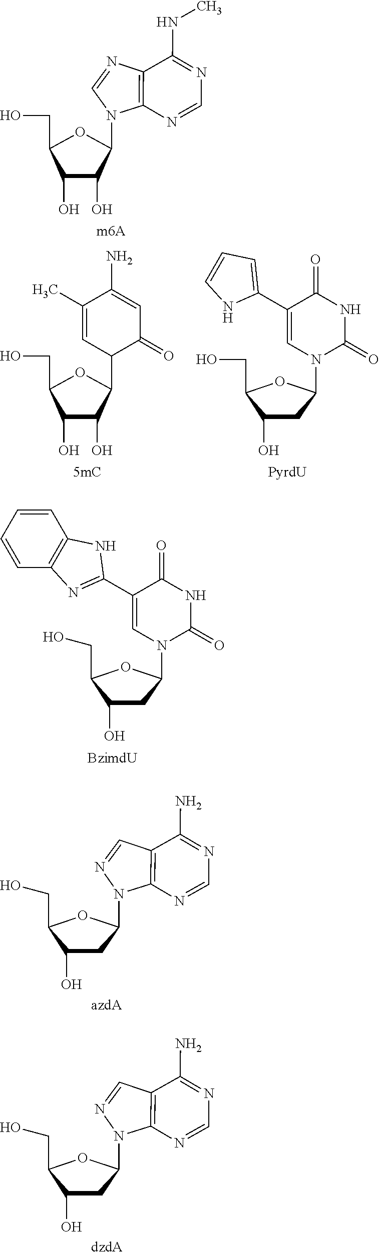

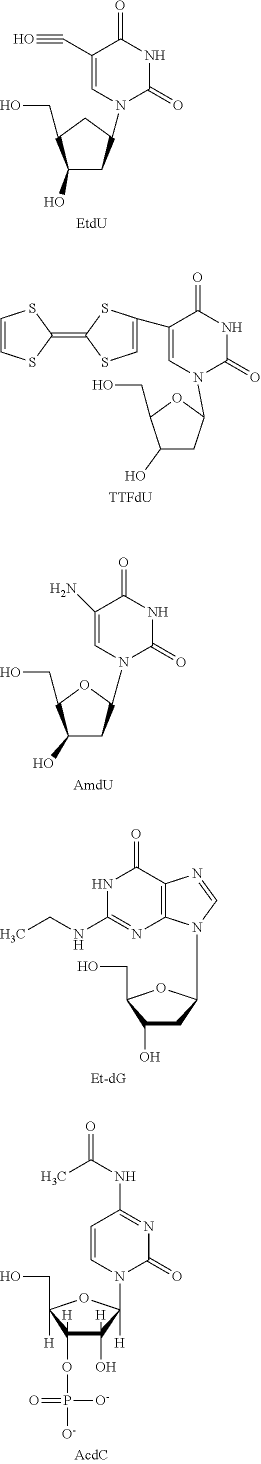

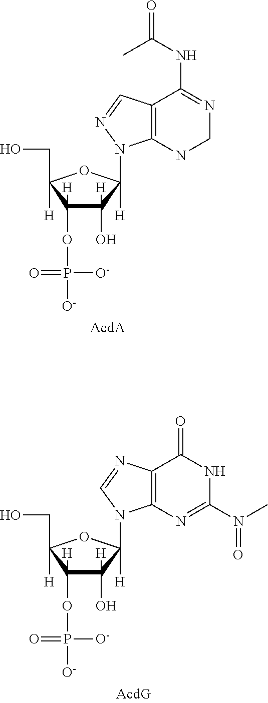

(7) The molecular memory according to (1) above, wherein a first conductance range and a second conductance range do not overlap each other, the first conductance range being a range from the minimum value to the maximum value of conductance of the molecules included in the first molecule group, and the second conductance range being a range from the minimum value to the maximum value of conductance of the molecules included in the second molecule group.
(8) The molecular memory according to (6) above, wherein a first conductance range and a second conductance range do not overlap each other, the first conductance range being a range from the minimum value to the maximum value of conductance of the molecules included in the first molecule group, and the second conductance range being a range from the minimum value to the maximum value of conductance of the molecules included in the second molecule group.
(9) The molecular memory according to (1) above,
   wherein the address region includes
      a first address region connected to one end of the memory region, and
      a second address region connected to the other end of the memory region,
   wherein the first address region is constituted of four or more types of molecules selected from a second-a molecule group,
   wherein the second address region is constituted of four or more types of molecules selected from a second-b molecule group,
   wherein the molecules included in the first molecule group
      all are of different types from the types of the molecules included in the second-a molecule group, or
      include the same type as and a different type from the types of the molecules included in the second-a molecule group, and
      all are of different types from the types of the molecules included in the second-b molecule group, or
      include the same type as and a different type from the types of the molecules included in the second-b molecule group, and
   wherein the molecules included in the second-b molecule group
      all are of different types from the types of the molecules included in the second-a molecule group, or
      include the same type as and a different type from the types of the molecules included in the second-a molecule group.
(10) The molecular memory according to (9) above,
   wherein the types of the molecules included in the first molecule group, the types of the molecules included in the second-a molecule group, the types of the molecules included in the second-b molecule group all differ from each other,
   wherein one of the second-a molecule group and the second-b molecule group includes four or more types of molecules selected from a group consisting of:

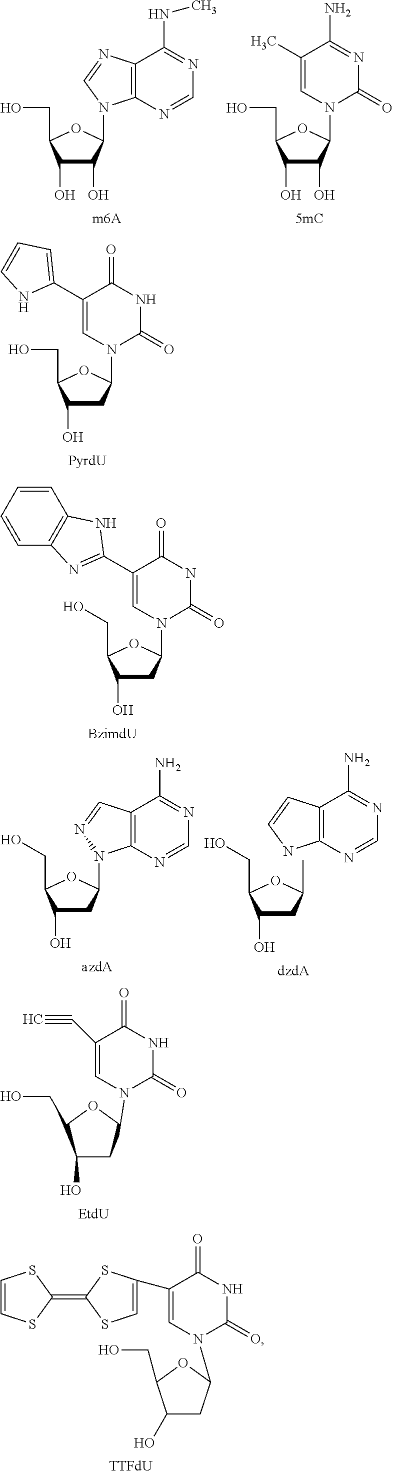

and
wherein the other of the second-a molecule group and the second-b molecule group includes four or more types of molecules selected from a group consisting of:

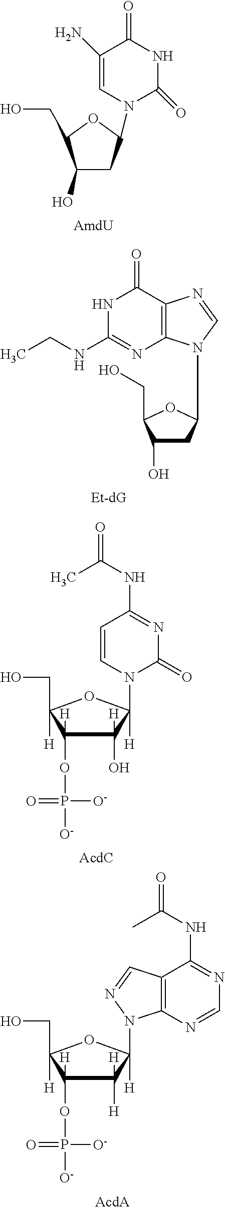

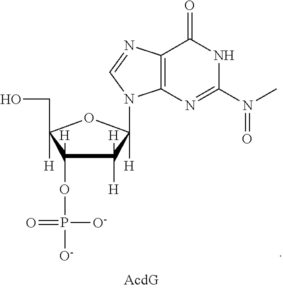

(11) The molecular memory according to (1) above,
   wherein a redundant region is connected between the address region and the memory region, and
   wherein the redundant region is constituted of a redundant region molecule that generates tunnel current, and the conductance of the redundant region molecule is smaller than the conductance of molecules constituting the address region and the memory region.
(12) The molecular memory according to (9) above,
   wherein a first redundant region is connected between the first address region and the memory region,
   wherein a second redundant region is connected between the second address region and the memory region, and
   wherein the first redundant region and the second redundant region are constituted of redundant region molecules that generate tunnel current, and the conductance of the redundant region molecules is smaller than the conductance of molecules constituting the first address region, the second address region, and the memory region.
(13) A production method of the molecular memory according to any one of (1) to (12) above, the production method comprising:
   an information preparation step of preparing information to be encoded;
   a molecular sequencing step of converting the prepared information into molecules constituting a molecular memory to determine a sequence of the molecular memory; and
   a synthesis step of synthesizing molecules constituting the molecular memory based on the determined sequence.
(14) A device for decoding the molecular memory according to any one of (1) to (12) above, the device comprising:
   a base member;
   a channel formed in the base member;
   a pair of measuring electrodes used for measuring tunnel current occurring when the molecular memory passes between the measuring electrodes; and
   an analysis unit,
   wherein the channel includes
      a molecular memory input channel,
      a molecular memory measurement channel in which the measuring electrodes are arranged,
      a first taper channel arranged between the molecular memory input channel and the molecular memory measurement channel and having a decreasing channel width from the molecular memory input channel to the molecular memory measurement channel, and
      a molecular memory collection channel used for collecting the molecular memory that passed through the molecular memory measurement channel,
   wherein the width of a connection portion between the first taper channel and the molecular memory measurement channel is 20 nm to 200 nm, and
   wherein the analysis unit is configured to
      determine the direction of the molecular memory passing between the measuring electrodes based on the conductance of molecules constituting the address region and the conductance of molecules constituting the memory region, or
      determine the direction of the molecular memory passing between the measuring electrodes based on the conductance of molecules constituting the first address region and the conductance of molecules constituting the second address region.
(15) A decoding method of the molecular memory according to any one of (1) to (12) above by using the device according to (14) above, the decoding method comprising: a molecular memory electrophoresis step; a measurement step; an analysis step; and a molecular memory passage direction determination step,
   wherein the molecular memory electrophoresis step applies a voltage across the molecular memory input channel and the molecular memory collection channel to electrophorese a molecular memory in the molecular memory input channel toward the molecular memory collection channel,
   wherein the measurement step measures tunnel current occurring when the molecular memory passes through a gap between the pair of measuring electrodes arranged in the molecular memory measurement channel,
   wherein the analysis step analyzes a sequence of molecules constituting the molecular memory from a measurement result of the measured tunnel current, and
   wherein molecular memory passage direction determination step
      determines the direction of the molecular memory passing between the measuring electrodes based on the conductance of molecules constituting the address region and the conductance of molecules constituting the memory region, or
      determines the direction of the molecular memory passing between the measuring electrodes based on the conductance of molecules constituting the first address region and the conductance of molecules constituting the second address region.

### Advantageous Effects of Invention

The molecular memory disclosed in the present application can read constituent molecules on a molecule basis. Thus, by designing the molecular memory so that at least some of the molecules constituting the address region differ in types from at least some of the molecules constituting the memory region, it is possible to distinguish the address region and the memory region from each other and increase the capacity.

### BRIEF DESCRIPTION OF DRAWINGS

FIG. 1 is a schematic diagram illustrating an overview of a molecular memory 100.

FIG. 2 is a schematic diagram illustrating an overview of a molecular memory 100a.

FIG. 3 is a schematic diagram illustrating an overview of molecular memories 100′ and 100a′.

FIG. 4 is a schematic diagram illustrating an overview of a device 1.

FIG. 5A is a top view illustrating a relationship between channels of the device 1.

FIG. 5B is an arrow X-X sectional view of FIG. 5A.

FIG. 5C is an arrow Y-Y sectional view of FIG. 5A.

FIG. 6 is a schematic diagram illustrating an example of a procedure of fabricating channels and measuring electrodes in a base member.

FIG. 7 is a flowchart illustrating an example of a decoding method.

### DESCRIPTION OF EMBODIMENTS

A molecular memory, a production method of a molecular memory, a decoding method of a molecular memory, and a device for decoding a molecular memory will be described below in detail with reference to the drawings.

In the present specification, members having the same type of functions are labeled with the same or similar references. Further, for the members labeled with the same or similar references, duplicated description thereof may be omitted.

In the present specification, a range of numerical values expressed by using “to” means a range including the numerical values written before and after “to” as the lower limit value and the upper limit value. A numerical value, a range of numerical values, and a quantitative expression (for example, expressions such as “the same”, “substantially”, or the like) are intended to be construed as indicating a numerical value, a range of numerical values, and a nature that contain an error generally acceptable in this technical field.

Further, some position, size, range, or the like of each component illustrated in the drawing do not express the actual position, size, range, or the like for easier understanding. Thus, the disclosure of the present application is not necessarily limited to the position, size, range, or the like disclosed in the drawings.

### [Embodiment of Molecular Memory]

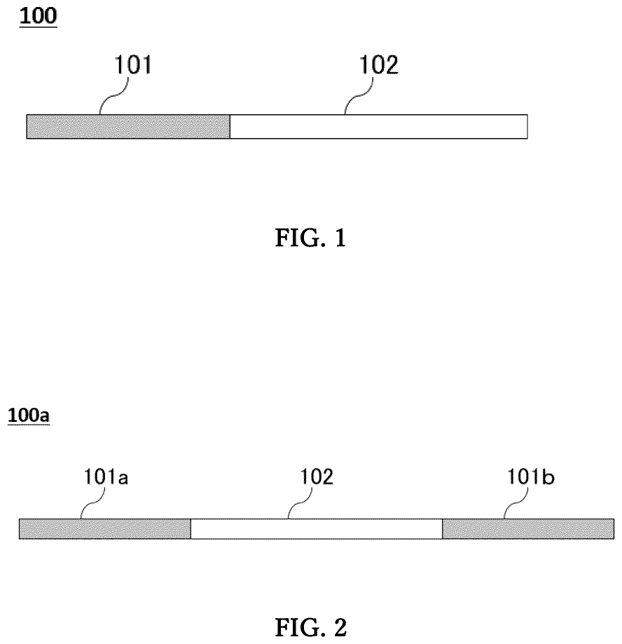

An embodiment of a molecular memory 100 will be described with reference to FIG. 1 to FIG. 3. FIG. 1 to FIG. 3 are schematic diagrams illustrating an overview of the molecular memory 100.

The molecular memory 100 includes an address region 101 and a memory region 102 connected to the address region 101. The address region 101 and the memory region 102 are constituted of molecules that generate tunnel current. The memory region 102 is constituted of four or more types of molecules selected from a first molecule group, and the molecules constituting the address region 101 are constituted of four or more types of molecules selected from a second molecule group. Further, the molecules included in the first molecule group may all be of different types from the types of molecules included in the second molecule group or may include the same type as and different types from the types of molecules included in the second molecule group. Thus, the molecular memory 100 according to the embodiment is configured such that at least some of the molecules constituting the address region 101 differ in types from at least some of the molecules constituting the memory region 102.

The molecules constituting the molecular memory 100 are not particularly limited as long as they can generate tunnel current and connect the molecules to each other. Although not limited to, the following molecules may be used.
(1) Nucleosides: Adenosine (A), Thymidine (T), Guanosine (G), Cytidine (C), Uridine (U), modifications of these nucleosides, and artificial nucleosides.
(2) Organic semiconductor molecules: thiophene, pyridine, naphthalene, pentacene, anthracene, rubrene, phthalocyanine, perylene, Alq3, pyrrole, aniline, and derivatives of these molecules
(3) Amino acids: Ala, Arg, Asn, Asp, Cys, Gln, Glu, Gly, His, Ile, Leu, Lys Met, Phe, Pro, Ser, Thr, Trp, Tyr, Va, or the like, acetylated amino acids, and methylated amino acids
(4) Glycans: a, β glucose and isomers thereof, pentoses, hexoses, and amino sugars or the like.

The molecular memory 100 according to the embodiment can be identified on a molecule basis based on a difference in conductance of constituent molecules by a decoding method of the molecular memory 100 using a device for decoding a molecule memory described later. The molecular memory 100 has an elongated shape, and when decoded by using a device described later, a case where the decoding starts on the address region 101 side of the elongated molecular memory 100 and a case where the decoding starts on the memory region 102 side are mixed. However, when the types of molecules included in the first molecule group all differ from the types of molecules included in the second molecule group, the types of molecules constituting the address region 101 all differ from the types of molecules constituting the memory region 102. In such a case, the address region 101 and the memory region 102 can be easily determined based on the types of the read molecules.

Next, description will be provided for a case where the molecules included in the first molecule group and the molecules included in the second molecule group include the same type and different types of molecules and, as a result, the types of the molecules constituting the address region 101 include the same type as and different types from those of the molecules constituting the memory region 102. In designing the molecular memory 100, it is possible to set the length of the address region 101 and the length of the memory region 102 in advance. Therefore, when the molecular memory 100 is read on a molecule basis, the address region 101 and the memory region 102 can be determined based on the position where the molecule included in only the address region 101 and/or the molecule included in only the memory region 102 was read, the length of the address region 101, and the length of the memory region 102.

Note that, when the molecules included in the first molecule group and the molecules included in the second molecule group include the same type of molecules, optionally and additionally, the molecular memory 100 may be designed so that the same type of molecule is arranged neither at the terminal on the memory region 102 side of the address region 101 nor at the terminal on the address region 101 side of the memory region 102. When the same type of molecule is not arranged at the connection portion between the address region 101 and the memory region 102, this makes it easier to determine the address region 101 and the memory region 102.

The molecular memory 100 disclosed in the present application is identified by using conductance. The present inventors have newly found through experiments that, when an elongated molecule is measured by using tunnel current, the reading accuracy is slightly lower in a terminal portion of the elongated molecule than in the center portion thereof. A conceivable reason therefor is that, while the terminal portion of the elongated molecule is affected by thermal motion, the center portion is less affected by thermal motion. Further, it has been newly found through experiments that, when molecules are read by using conductance, electrical noise from a device affects the accuracy in reading molecules.

Based on the above knowledge obtained from experiments, optionally and additionally, the molecular memory 100 may be designed so that a molecule having the smallest conductance in the molecules included in the first molecule group is not arranged at the terminal on the memory region 102 which is the opposite side from the address region 101 side, and a molecule having the smallest conductance in the molecules included in the second molecule group is not arranged at the terminal on the address region 101 which is the opposite side from the memory region 102 side. When a molecule having the smallest conductance in the molecule group constituting each region is not arranged at the terminal of the molecular memory 100, in other words, a molecule having a high conductance in the molecule groups is arranged at the terminal thereof, the accuracy in reading molecules is higher even when affected by electrical noise or thermal motion. While it is most preferable that a molecule having the highest conductance in the molecule group constituting each region be arranged at the terminal of the molecular memory 100, a molecule having the second highest conductance may be arranged at the terminal thereof, naturally. Arrangement in which a molecule other than a molecule having the smallest conductance among molecules that can be selected is arranged at the terminal of the molecular memory can improve the accuracy in reading molecules compared to a case where the conductance of molecules constituting each region is not at all considered.

The first molecule group constituting the memory region 102 may be, for example, molecules listed in <Molecule group 1> below as examples. Note that the following molecules are mere examples, and the disclosure is not limited thereto. Further, the molecules listed in <Molecule group 1> below as examples may be used as the second molecule group.

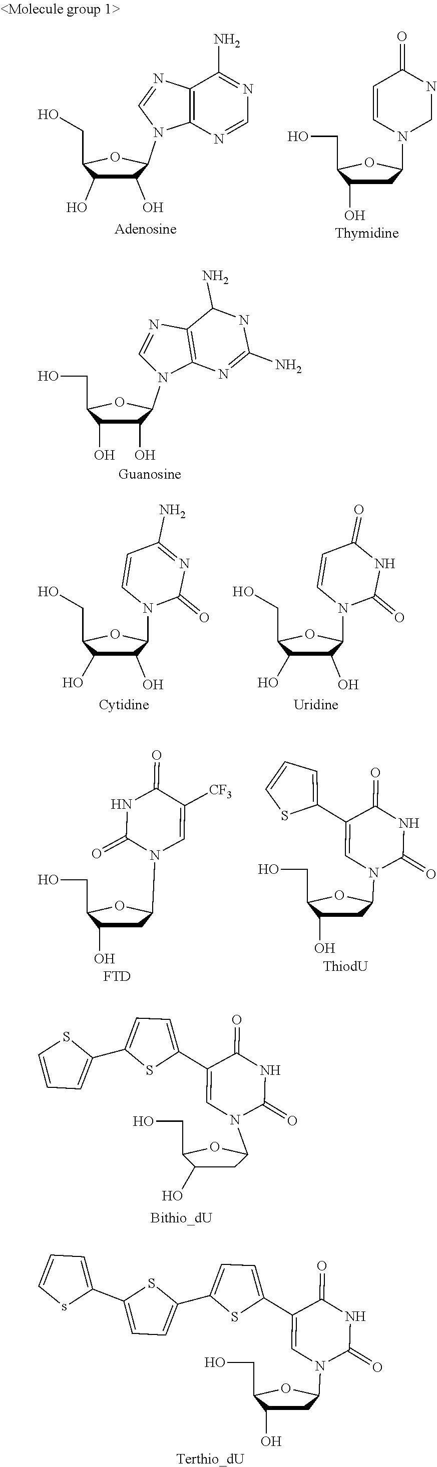

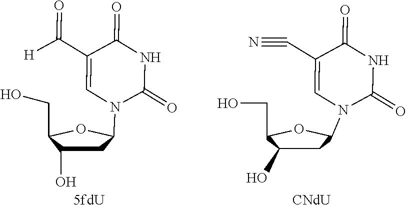

Further, the second molecule group constituting the address region 101 may be, for example, molecules listed in <Molecule group 2> and <Molecule group 3> below as examples. Note that the following molecules are mere examples, and the disclosure is not limited thereto. Further, the molecules listed in <Molecule group 2> and <Molecule group 3> below as examples may be used as the first molecule group.

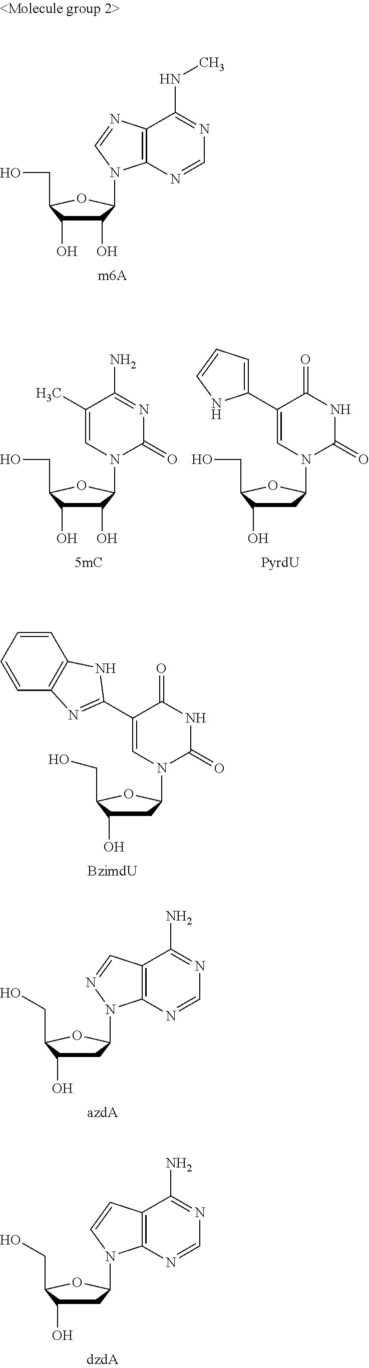

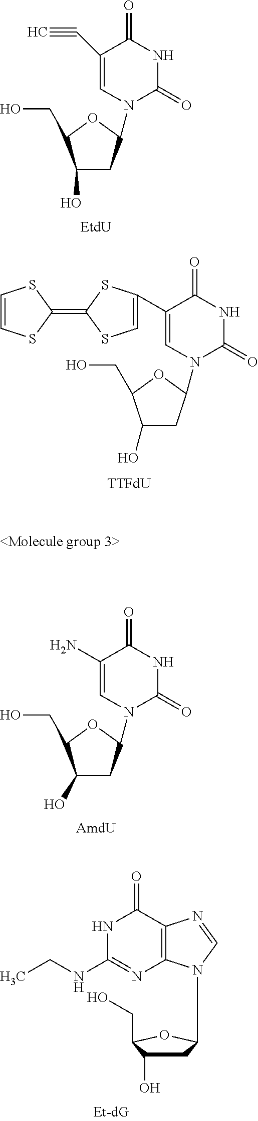

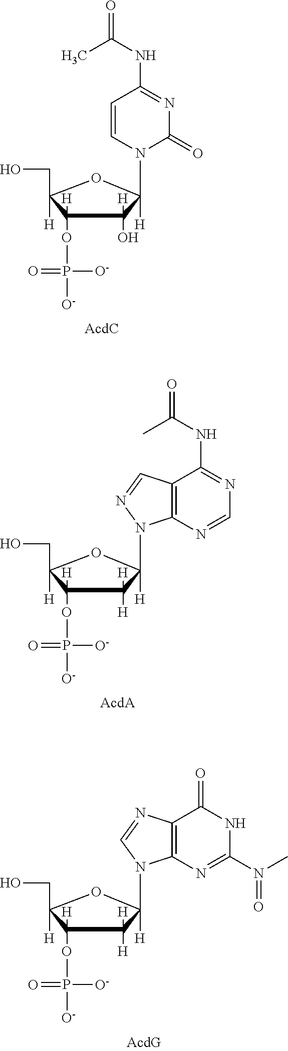

Further, Table 1 lists values of the conductance and the relative G of the compounds listed as examples above in <Molecule group 1>, <Molecule group 2>, and <Molecule group 3>. Note that the conductance and the relative Glisted in Table 1 are values measured by using the device 1 described later. Further, the technical significance of the conductance and the relative G will be described later.

TABLE 1

| | | Conductance(pS) | Relative G |
|---|---|---|---|
| Molecule group 1 | adenosine | 92.3 | 0.75 |
| | guanosine | 123.0 | 1 |
| | cytidine | 71.3 | 0.58 |
| | thymine | 50.4 | 0.41 |
| | uridine | 46.7 | 0.38 |
| | FTD | 25.8 | 0.21 |
| | thiodU | 76.3 | 0.62 |
| | Bithio_dU | 88.6 | 0.72 |
| | Terthio_dU | 108.2 | 0.88 |
| | 5fdU | 93.5 | 0.76 |
| | CNdU | 91.0 | 0.74 |
| Molecule group 2 | m6A | 110.7 | 0.9 |
| | 5mC | 148.8 | 1.21 |
| | PyrdU | 157.4 | 1.28 |
| | BzimidU | 203.0 | 1.65 |
| | azdA | 162.4 | 1.32 |
| | dzdA | 155.0 | 1.26 |
| | EtdU | 221.4 | 1.8 |
| | TTFdU | 270.6 | 2.2 |
| Molecule group 3 | AmdU | 108.2 | 0.88 |
| | Et-dG | 137.8 | 1.12 |
| | AcdC | 125.5 | 1.02 |
| | AcdA | 137.8 | 1.12 |
| | AcdG | 159.9 | 1.3 |

A different molecular structure results in different conductance. Therefore, while the molecular memory 100 described above enables molecules to be identified based on conductance, optionally and additionally, the molecular memory 100 may be designed so that conductance values of molecules constituting the address region 101 and the memory region 102 do not overlap each other. More specifically, molecules included in each group need to be selected so that a first conductance range, which is a range between the minimum conductance value and the maximum conductance value of the molecules included in the first molecule group, and a second conductance range, which is a range between the minimum conductance value and the maximum conductance value of the molecules included in the second molecule group, do not overlap each other. When the molecular memory 100 is designed so that conductance values of respective molecules constituting the address region 101 and the memory region 102 do not overlap each other, this achieves an advantageous effect that it is possible to easily distinguish the address region 101 and the memory region 102 from each other and it is possible to easily determine from which region side the decoding was started.

When the first conductance range and the second conductance range are designed so as not to overlap each other, the first conductance range may be higher than the second conductance region, and the first conductance range may be lower than the second conductance range.

Note that setting the first conductance range and the second conductance range to not overlap each other is optional and additional design as described above. Even when the first conductance range and the second conductance range partially overlap each other, since a different molecular type results in different conductance, types of molecules can be determined. For example, in the example indicated in Table 1, the conductance range of the first molecule group is 25.8 (FTD) to 123.0 (guanosine). On the other hand, the conductance of the second molecule group is 108.2 (AmdU) and 110.7 (m6A) to 270.6 (TTFdU). In the example indicated in Table 1, when molecules included in the second molecule group are designed, the molecules may be designed to include AmdU and/or m6A or may be designed to not include AmdU and/or m6A. Even when the first conductance range and the second conductance range partially overlap each other, the conductance distribution differs between a region constituted of molecules of the first conductance range and a region constituted of molecules of the second conductance range. Therefore, distinction between the address region 101 and the memory region 102 and determination about from which region side the decoding was started are easier compared to design without consideration of the conductance range.

The types of molecules constituting the address region 101 and the memory region 102 can be designed as appropriate in accordance with a target capacity. For example, 4 types, 8 types, 16 types, or the like of molecules can be selected from a number of molecules included in molecule groups constituting respective regions. Note that, in typical memories, the number of types is limited to power of two. In contrast, the molecular memory 100 disclosed in the present application can read constituent molecules on a molecule basis. Thus, for example, when different types of molecules from the molecules arranged within the same region are arranged only at terminals of respective regions, the terminals of the regions can be identified, and various types of design are made possible, such as arranging molecules different in types from the molecules within the same region only in the portion to which a particular function is added even within that same region. Therefore, the number of types of molecules constituting respective regions of the molecular memory 100 disclosed in the present application may be 5 to 7, 9 to 15, or 17 or greater.

Note that, in the molecular memory 100, desired information is encoded by combination of constituent molecules. For example, it is provided that types of molecules included in the first molecule group constituting the memory region 102 are four types of A, B, C, and D, and the length of the memory region 102 is L. In such a case, for the memory region 102 fabricated by encoding information, various sequences are included in the length of L, such as a case where all the molecules constituting the length L are of the type A; a case where the molecules constituting the length L are of only the types A and B; a case where the molecules constituting the length L include all the four types A to D; or the like in accordance with the content of information to be encoded. Therefore, the types of molecules included in the first molecule group and the second molecule group and the types of molecules constituting an actually fabricated molecular memory are not necessarily required to completely match each other.

The lengths of the address region 101 and the memory region 102 are not particularly limited as long as they are lengths that enable synthesis of molecules constituting the molecular memory 100. Note that, in the molecular memory 100 according to the embodiment, constituent molecules can be read on a molecule basis, various types of molecules can be used, and thus, a large amount of information can be stored within a short length.

For example, it is assumed that the address region 101 has a length of 20 molecules using 16 types of molecules, and it is assumed that the memory region 102 has a length of 100 molecules using 4 types of molecules. In such a case, the total memory capacity will be as follows.
(1) The number of possible combinations of the address region 101 16²⁰=2⁸⁰
(2) The number of bytes of the memory region 102
   4 types of molecules→4=2²→2 bits
   2 bits×100=200 bits
   200/8=25 bytes
(3) The total memory capacity
   25 bytes×2⁸⁰
   where, since 2¹⁰=1024≈10³, 25 bytes×2⁸⁰→25 bytes×10²⁴→25 yottabytes.

A capacity of 25 yottabytes is a capacity that surpasses the storage capacity produced by mankind.

The molecular memory 100 according to the embodiment achieves the following advantageous effects.
(a) While the conventional DNA memories combine four types of DNA, the molecular memory 100 according to the embodiment differentiates the types of molecules constituting the address region 101 from the types of molecules constituting the memory region 102 so that both the types do not completely match each other. Therefore, since the number of combinations of molecules can be increased, a large amount of information can be stored even when the molecular memory 100 is short.
(b) The molecular memory 100 has an elongated shape. Thus, the direction in which the molecular memory 100 passes between measuring electrodes of a device used for decoding the molecular memory 100 is not constant. Because the molecular memory 100 is designed such that the types of molecules constituting the address region 101 do not completely match the types of molecules constituting the memory region 102, the direction in which the molecular memory 100 passes between the measuring electrodes can be easily determined.
(c) When the molecular memory 100 is designed such that the first conductance range and the second conductance range do not completely overlap or do partially overlap each other, this makes it easier to distinguish the address region 101 and the memory region 102 from each other in decoding the molecular memory 100. Therefore, the boundary between the address region 101 and the memory region 102 can be accurately read, which results in less storage errors.

Next, examples of optional and additional configurations that can be employed by the molecular memory 100 will be described.

### [First Address Region and Second Address Region]

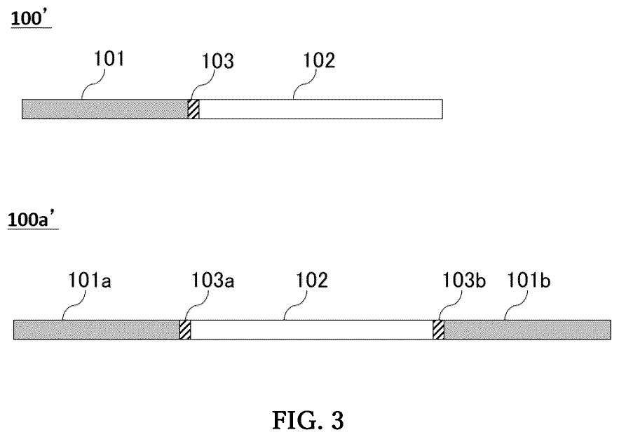

While the molecular memory 100 illustrated in FIG. 1 has a single address region 101, a molecular memory 100a may include two address regions as illustrated in FIG. 2. In the example illustrated in FIG. 2, the molecular memory 100a includes a first address region 101a connected to one end of the memory region 102 and a second address region 101b connected to the other end of the memory region 102.

The first address region 101a is constituted of two or more types of molecules selected from a second-a molecule group, and the second address region 101b is constituted of two or more types of molecules selected from a second-b molecule group. The relationship between the molecules constituting the first address region 101a and the molecules constituting the memory region 102 and the relationship between the molecules constituting the second address region 101b and the molecules constituting the memory region 102 each are the same as the relationship between the molecules of the address region 101 and the memory region 102 described above. Specifically, the molecules included in the first molecule group all are of different types from the types of the molecules included in the second-a molecule group or include molecules of the same type(s) as and a different type(s) from the types of the molecules included in the second-a molecule group and all are of different types from the types of the molecules included in the second-b molecule group or include molecules of the same type(s) as and a different type(s) from the types of the molecules included in the second-b molecule group. That is, it is only required that the types of the molecules constituting the first address region 101a and the second address region 101b do not completely match the types of the molecules constituting the memory region 102.

Note that, when the first address region 101a and the second address region 101b are included, it is required to distinguish the first address region 101a and the second address region 101b from each other. Thus, the molecular memory 100a can be designed so that the molecules included in the second-b molecule group all are of different types from the types of molecules included in the second-a molecule group or include molecules of the same type(s) as and a different type(s) from the types of the molecules included in the second-a molecule group.

Even when including the first address region 101a and the second address region 101b, the design concept on the molecular memory 100a is the same as that on the molecular memory 100 including the address region 101 and the memory region 102. Therefore, the features described for the molecular memory 100 are applicable to the molecular memory 100a.

For example, when the first molecule group includes molecules of the same type as the molecules included in the second-a molecule group and the second-b molecule group, it is preferable that the same type of molecules be neither arranged at both terminals of regions of the connection portion between the first address region 101a and the memory region 102 nor arranged at both terminals of regions of the connection portion between the second address region 101b and the memory region 102.

Further, it is preferable that the molecule included in the second-a molecule group and the second-b molecule group and having the smallest conductance in the molecules thereof be not arranged at the terminal of the first address region 101a and/or the terminal of the second address region 101b that is opposite side from the memory region 102 side.

Further, when the range from the minimum value to the maximum value of the conductance of molecules included in the second-a molecule group is denoted as a second-a conductance range, and the range from the minimum value to the maximum value of the conductance of molecules included in the second-b molecule group is denoted as a second-b conductance range, any of the followings may be applied:
first conductance range>second-a conductance range>second-b conductance range,
first conductance range>second-b conductance range>second-a conductance range,
second-a conductance range>first conductance range>second-b conductance range,
second-a conductance range>second-b conductance range>first conductance range,
second-b conductance range>first conductance range>second-a conductance range,
second-b conductance range>second-a conductance range>first conductance range.

Further, the first conductance range, the second-a conductance range, and the second-b conductance range may be designed so that respective ranges do not completely overlap each other or may be designed so that respective ranges partially overlap each other.

Note that, as described above, when an elongated molecule is measured by using tunnel current, the measured reading accuracy is slightly lower at the terminal portion than at the center portion of the elongated molecule. Further, in terms of storing information, the memory region 102 is of higher importance than the first address region 101a and the second address region 101b. Accordingly, when the first address region 101a and the second address region 101b are provided, the following settings are preferable in view of reading accuracy:
second-a conductance range>second-b conductance range>first conductance range,
second-b conductance range>second-a conductance range>first conductance range.

The second-a molecule group may be, for example, one of the groups illustrated above as examples in <Molecule group 2> and <Molecule group 3>, and the second-b molecule group may be the other of <Molecule group 2> and <Molecule group 3>. Note that the molecules thereof are mere examples and not limited thereto.

When two address regions are provided, the following advantageous effects are achieved in addition to the advantageous effects described above in (a) to (d) achieved by the molecular memory 100.
(e) With two address regions being provided, although the total length constituting a molecular memory is slightly longer, the same capacity as that of the molecular memory 100 can be obtained with fewer types of molecules. For example, it is assumed that the first address region 101a has the length of 20 molecules using 4 types of molecules, the memory region 102 has the total length of 100 molecules using 4 types of molecules, and the second address region 101b has the length of 20 molecules using 4 types of molecules. In such a case, the total memory capacity will be as follows.
(1) The number of possible combinations of the first address region 101a 4²⁰=2⁴⁰
(2) The number of possible combinations of the second address region 101b 4²⁰=2⁴⁰
(3) The number of bytes of the memory region 102
   4 types of molecules→4=2²→2 bits
   2 bits×100=200 bits
   200/8=25 bytes
(4) The total memory capacity
   25 bytes×2⁴⁰×2⁴⁰=25 bytes×2⁸⁰
   where, since 2¹⁰=10²⁴≈10³, 25 bytes×2⁸⁰→25 bytes×10²⁴→25 yottabytes.

With the molecular memory 100 illustrated in FIG. 1, a capacity of 25 yottabytes is obtained with 20 types in total and 120 molecules in total length. On the other hand, with the molecular memory 100a illustrated in FIG. 2, a capacity of 25 yottabytes is obtained with 12 types in total and 140 molecules in total length. Because the required number of types of molecules can be reduced, the flexibility in selection of molecules having a certain conductance difference therebetween is improved. Further, the larger the difference in conductance between molecules is, the fewer the reading errors in measuring tunnel current will be. Therefore, in the molecular memory 100a illustrated in FIG. 2, the reading accuracy can be improved by suitably selecting constituent molecules.
(f) As described above, when an elongated molecule is measured by using tunnel current, the reading accuracy is slightly lower at the terminal portion than at the center portion of the elongated molecule. However, because the memory region 102 storing information is arranged between the first address region 101a and the second address region 101b, the reading accuracy for the memory region 102 storing information can be higher than in the molecular memory 100.
(g) In the case of the structure in which the memory region 102 is interposed between the first address region 101a and the second address region 101b each having larger conductance than the memory region 102, this makes clear distinction between the memory region 102 and the first address region 101a and clear distinction between the memory region 102 and the second address region 101b.
(h) Further, in the case of the structure in which the memory region 102 is interposed between the first address region 101a and the second address region 101b each having larger conductance than the memory region 102, because molecules having high conductance are arranged on both end sides of the molecular memory, it is possible to prevent a reduction in reading accuracy due to the effect of thermal motion or the like.

### [Redundant Region]

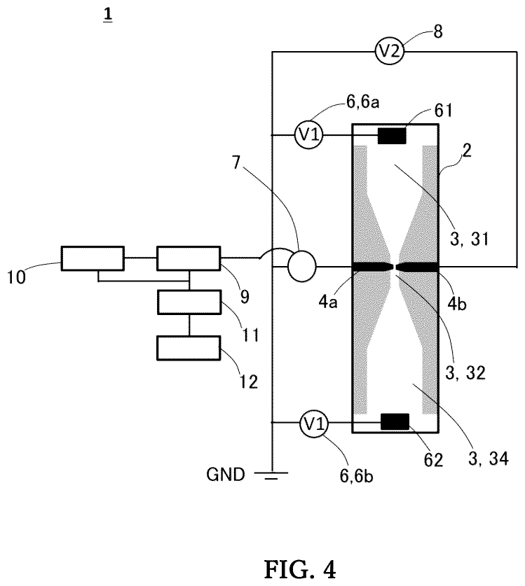

As illustrated in FIG. 3, in the molecular memory 100, a redundant region 103 may be connected between the address region and the memory region (molecular memory 100′). Further, in the molecular memory 100a, a first redundant region 103a may be connected between the first address region 101a and the memory region 102, and a second redundant region 103b may be connected between the second address region 101b and the memory region 102 (molecular memory 100a′). The redundant regions 103, 103a, and 103b are each constituted of redundant region molecules that generate tunnel current, and the conductance of the redundant region molecules is designed to be smaller than the conductance of molecules constituting the (first, second) address region 101 and the memory region 102.

The redundant region molecule is not particularly limited as long as it has smaller conductance than the molecules constituting the (first, second) address region 101 and the memory region 102 and can connect the molecules to each other. The redundant region molecule may be, for example, but is not limited to, the following compounds.

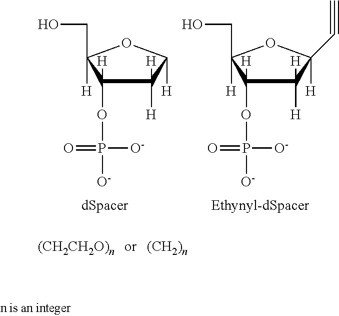

The redundant regions 103, 103a, and 103b are each provided to facilitate distinction between the (first, second) address region 101 and the memory region 102. Therefore, each length of the redundant regions 103, 103a, and 103b may be short and may be, for example, around two molecules, three molecules, four molecules, five molecules, six molecules, seven molecules, or eight molecules. Note that, in the example illustrated in FIG. 3, the redundant regions 103, 103a, and 103b are each connected between the (first, second) address region 101 and the memory region 102. Although not illustrated, the redundant region may also be connected to the end of the address region (the left end of the address region 101 in the case of the molecular memory 100′; the left end of the first address region 101a and/or the right end of the second address region 101b in the case of the molecular memory 100a′) in addition to the locations illustrated in FIG. 3. Further, in the case of the molecular memory 100′, the redundant region may be connected to the other terminal of the memory region 102.

When the redundant region 103, 103a, 103b is provided, the following advantageous effects are achieved in addition to the advantageous effects described above in (a) to (h) achieved by the molecular memories 100 and 100a.
(i) With the redundant region being provided, this makes clearer distinction between the (first, second) address region 101 and the memory region 102.
(j) A sequence for recovering information even when molecules are skipped and read in decoding (sequence serving as duplicated information) can be added to the redundant region (for example, the same sequence is repeated, a sequence with information+1 is created, or the like). When such a sequence is added, reproduction of information can be ensured.
(k) For information security reasons, a sequence corresponding to an encryption code can be inserted in the redundant region (for example, to enable reconstruction of original information by using a decryption code). In such a case, information leakage can be prevented.
(l) Further, when the redundant region is also connected to the end of the address region (the left end of the address region 101 in the case of the molecular memory 100′; the left end of the first address region 101a and/or the right end of the second address region 101b in the case of the molecular memory 100a′), the advantageous effect described in (i) described above is obtained.

The embodiments of the molecular memories described above are examples for easier understanding. The embodiments may be modified, such as combining various design examples, as long as such a modification is within the scope of the technical concept disclosed in the present application.

### [Embodiment of Production Method of Molecular Memory]

Next, an embodiment of a production method of a molecular memory will be described. The embodiment of the production method includes an information preparation step, a molecular sequencing step, and a synthesis step.

The information preparation step is to prepare information to be encoded. For example, information is acquired, and analog data is converted as preparation into digital data.

The molecular sequencing step is to convert prepared information into molecules constituting a molecular memory and determine the sequence of the molecular memory in encoding the information. For example, digital data to be stored in the memory region 102 is converted by using 4 types of molecules in a case of 2-bit data or by using 16 types of molecules in a case of 4-bit data, and the sequence is determined. Further, the (first, second) address region 101, which is a sequence tag for random access, is converted by using 4 types of molecules in a case of 2-bit data or by using 16 types of molecules in a case of 4-bit data to determine the sequence. Further, when the redundant region is provided, a sequence including the redundant region is determined. Note that, to avoid complication of description, the description of the redundant region will be omitted below.

The synthesis step is to synthesize molecules constituting the molecular memory based on the determined sequence. As a synthesizer, a known synthesizer may be used in accordance with molecules constituting the molecular memory 100, 100a. For example, when nucleosides are used as the molecules, a nucleic acid synthesizer can be used. When amino acids are used as the molecules, a protein synthesizer can be used. Further, when an organic semiconductor is introduced to a chain, peptide nucleic acids can be used, and a protein synthesizer may be used. Further, when a nucleoside or an organic semiconductor is mixed, hydrogen of the base molecule of the nucleoside can be substituted with a semiconductor molecule, and synthesis can be performed thereon by a nucleic acid synthesizer. Further, a base molecule and an organic semiconductor may be introduced to a peptide nucleic acid, and synthesis may be performed thereon by a protein synthesizer.

Note that, in the molecular sequencing step, the sequence is determined by using molecules included in the first molecule group and the second molecule group (the second-a molecule group, the second-b molecule group) described in the embodiment of the molecular memory 100, 100a. Then, the synthesis step is to synthesize the molecular memory 100, 100a by using the molecules included in the first molecule group and the second molecule group (the second-a molecule group, the second-b molecule group). Configuring the molecular memory 100, 100a such that at least some of the molecules constituting the (first, second) address region 101 and the memory region 102 are of different types by using the molecules included in first molecule group and the second molecule group (the second-a molecule group, the second-b molecule group) is a novel invention. Therefore, the molecular sequencing step and the synthesis step are also novel steps.

### [Embodiment of Device for Decoding Molecular Memory]

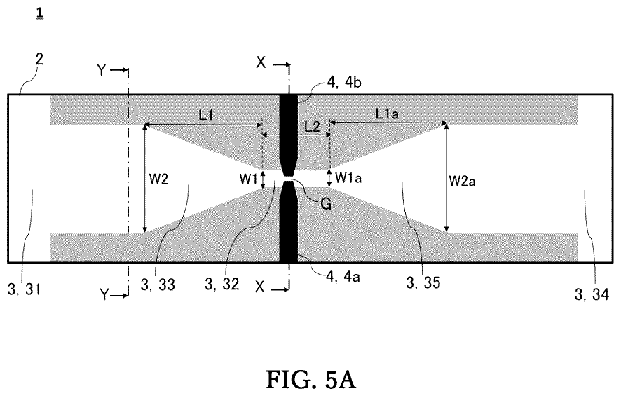

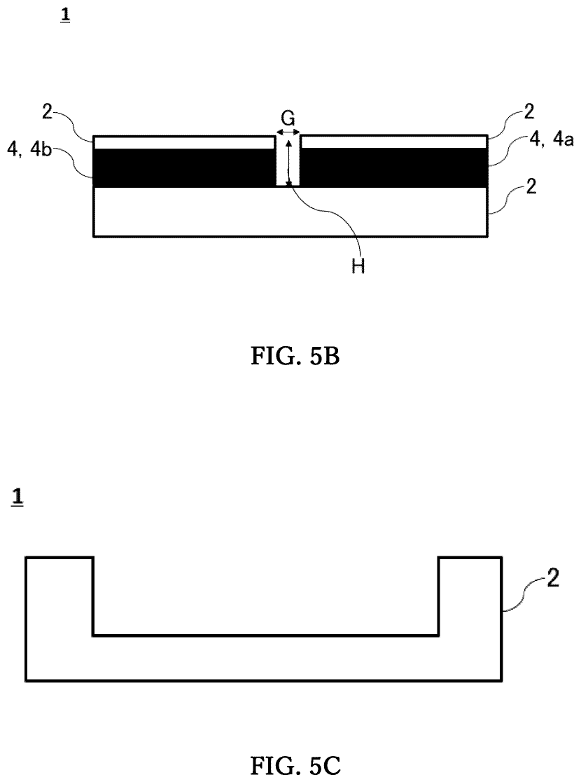

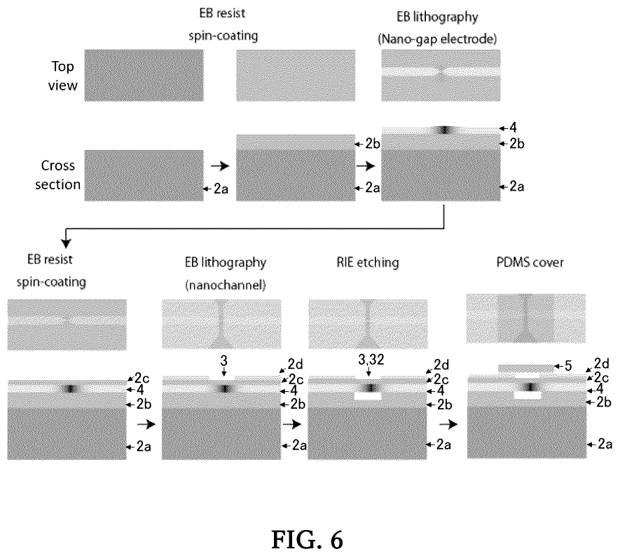

Next, an embodiment of the device 1 for decoding a molecular memory will be described with reference to FIG. 4, FIG. 5A to FIG. 5C, and FIG. 6. FIG. 4 is a schematic diagram illustrating an overview of the device 1. FIG. 5A is a top view illustrating a relationship of channels, FIG. 5B is the arrow X-X sectional view of FIG. 5A, and FIG. 5C is the arrow Y-Y sectional view of FIG. 5A. FIG. 6 is a schematic diagram illustrating an example of a procedure of fabricating channels and measuring electrodes in a base member.

In the example illustrated in FIG. 4 and FIG. 5A to FIG. 5C, the device 1 includes a base member 2, a channel 3 formed in the base member 2, a pair of measuring electrodes 4 (4a and 4b) for measuring tunnel current occurring when molecular memories pass therebetween, and an analysis unit 9. Note that, in the following, the portion of the base member 2, the channel 3, and the measuring electrodes 4 may be referred to as “measurement portion”. Further, FIG. 4 illustrates an example optionally and additionally including electrophoresis power supplies 6, 6a, 6b, an electrophoresis first electrode 61, an electrophoresis second electrode 62, a tunnel current detection unit 7, a tunnel current measuring power supply 8, a display unit 10, a program memory 11, and a control unit 12. Such an optional and additional configuration can be added, if necessary, when the decoding method of a molecular memory is performed. Further, in the following description, the molecular memory may correspond to the embodiment illustrated with the reference 100, 100a, 100′, or 100a′ or other embodiments. To avoid complication, the reference of the molecular memory will be omitted in the following description.

The channel 3 includes a molecular memory input channel 31 from which a solution containing molecular memories is input, a molecular memory measurement channel 32 in which the measuring electrodes 4 are arranged, a first taper channel 33 arranged between the molecular memory input channel 31 and the molecular memory measurement channel 32 and having a decreasing channel width from the molecular memory input channel 31 to the molecular memory measurement channel 32, and a molecular memory collection channel 34 that collects molecular memories that have passed through the molecular memory measurement channel 32. The width W1 of the connection portion between the first taper channel 33 and the molecular memory measurement channel 32 is 20 nm to 200 nm.

Although the second taper channel 35 is depicted in the example illustrated in FIG. 5A, the second taper channel 35 has an optional and additional configuration. The molecular memory collection channel 34 may be directly connected to the molecular memory measurement channel 32 as long as molecular memories that have flown out of the molecular memory measurement channel 32 can be collected.

The measurement portion can be produced by, for example, using Nanochannel-Integrated Mechanically Controllable Break Junction. An example of the production procedure will be illustrated with reference to FIG. 6. Note that a mechanically controllable break junction (MCBJ) for fabricating the pair of measuring electrodes 4 is disclosed in, for example, Japanese Patent Application Laid-Open No. 2019-525766; Patent Literature 1 listed above; M. Tsutsui, K., Shoji, M. Taniguchi, T. Kawai, Nano Lett., 345 (2008), M. Tsutsui, M. Taniguchi, T. Kawai, Appl. Phys. Lett.93, 163115 (2008); and the like.
(1) An insulating layer 2b is formed with an insulating material such as polyimide on a substrate 2a made of silicon or the like.
(2) A metal layer for forming the measuring electrodes 4 is deposited on the insulating layer 2b by electron beam (EB) lithography.
(3) A deposition layer 2c made of SiO₂ or the like is formed by chemical deposition. A resist layer 2d is layered on the deposition layer 2c by spin coating.
(4) A pattern of the channel 3 including the molecular memory measurement channel 32 is formed by electron beam lithography so as to overlap a metal layer used for forming the measuring electrodes 4.
(5) The channel 3 is formed by dry etching. A gap (nano-gap G) is then formed in a metal layer to form the measuring electrodes 4 by the MCBJ. Note that, although the molecular memory measurement channel 32 is etched to reach the part below the measuring electrodes 4 in the example illustrated in FIG. 6, the channel below the measuring electrodes 4 is not necessarily required to be provided. Further, although a single pair of measuring electrodes 4 are formed in the example illustrated in FIG. 6, two or more pairs of measuring electrodes 4 may be formed. Furthermore, in the electron beam lithography of (4) described above, a pattern for constructing a pillar (depiction is omitted in FIG. 5A and FIG. 5C) may be formed in the channel 3 except for the molecular memory measurement channel 32. By masking a portion where the pillar is to be formed so that the portion is not dry-etched, it is possible to form a pillar having one end connected to the bottom of the channel 3 except for the molecular memory measurement channel 32 and the other end opened upward.
(6) A cover member 5 in which a hole used for input of solution, insertion of the electrophoresis electrode, or the like is formed if necessary is attached. Note that the cover member 5 is attached at least during tunnel current measurement.

The substrate 2a is not particularly limited as long as it is a material generally used in the field of semiconductor manufacturing technologies. The material of the substrate 2a may be, for example, Si, SiOx, SiNx, Ge, Se, Te, GaAs, GaP, GaN, InSb, InP, or the like. Note that, with a pillar being provided in the channel 3 except for the molecular memory measurement channel 32, the contact area with a solution flowing in the channel 3 can be increased. Note that, as described later, when a measurement portion is formed so as to be symmetrical laterally with respect to the molecular memory measurement channel 32 as the center, pillars may also be formed in the molecular memory collection channel 34 and the second taper channel 35.

The insulating layer 2b is also not particularly limited as long as it is a material generally used in the field of semiconductor manufacturing technologies. The material of the insulating layer 2b may be, for example, insulating polymers such as polyimide, polypropylene, polyvinyl chloride, polystyrene, high-density polyethylene (HDPE), polyacetal (POM), or polyepoxy; insulating oxidized semiconductor metal materials such as SiO₂ or aluminum oxide; or the like.

The material forming the deposition layer 2c may be insulating polymers such as polyimide, polypropylene, polyvinyl chloride, polystyrene, high-density polyethylene (HDPE), polyacetal (POM), or polyepoxy; insulating oxidized semiconductor metal materials such as SiO₂ or aluminum oxide; or the like.

The material forming the measuring electrode 4 is not particularly limited as long as it enables measurement of tunnel current. The material may be, for example, gold, platinum, silver, palladium, tungsten, alloys of these metals, or the like.

The photoresist used in electron beam lithography and the reagent used in development, etching, and the like are not particularly limited as long as they are materials generally used in the field of microfabrication technologies. Further, a spin coater and an apparatus used in etching or the like are not particularly limited as long as they are apparatuses generally used in the field of micromachining technologies.

The cover member 5 in not particularly limited as long as it is a material that can be attached to the base member 2 in which the channel 3 is formed. The material of the cover member 5 may be, for example, polymethyldisiloxane (PDMS) or the like. For example, the cover member 5 and the base member 2 are attached to each other by ozone plasma treatment or the like.

Note that, in the present specification, “base member” means a material portion serving as a base used for forming the channel 3. In the example illustrated in FIG. 6, the base member 2 includes the substrate 2a, the insulating layer 2b, the deposition layer 2c, and the resist layer 2d. Note that FIG. 6 represents a mere example of a fabricating procedure of the measurement portion in which the measuring electrodes 4 are arranged in the molecular memory measurement channel 32. The measurement portion may be fabricated by adding other steps or deleting some of the steps as far as it enables measurement of tunnel current occurring when a molecular memory passes through. For example, after the channel 3 is formed by etching, the resist layer 2d may be removed. In such a case, the resist layer 2d is not included in the base member 2. Further, the measurement portion may be fabricated by electron beam engraving, nano-printing, or the like.

Further, in the example illustrated in FIG. 5A to FIG. 5C, for easier understanding, detailed representation of the substrate 2a, the insulating layer 2b, the deposition layer 2c, and the resist layer 2d is omitted, which are simply represented as the base member 2.

A voltage is applied across the molecular memory input channel 31 and the molecular memory collection channel 34, thereby electrophoresis force is applied to molecular memories, and the motion speed of the molecular memory is increased. As a result, compared to a case where no electrophoresis force is applied, the measurement speed of a molecular memory is improved. On the other hand, when a voltage is applied to the channel 3 to apply electrophoresis force to molecular memories, a larger sectional area of the channel 3 requires a larger voltage.

Reading of a molecular memory by using tunnel current is performed by identifying a difference in measured current values at a picoampere level. When a voltage at a level that can apply electrophoresis force is applied to molecular memories input to the channel of μm order, noise due to the voltage for electrophoresis may be detected by the measuring electrodes 4. Since the measurement portion illustrated in FIG. 5A to FIG. 5C can apply electrophoresis force to molecular memories at a low voltage, tunnel current with less noise caused by the voltage for electrophoresis can be measured.

The molecular memory input channel 31 requires a predetermined size in order to input a solution including molecular memories. Thus, the measurement portion employs the structure in which the width of the molecular memory measurement channel 32 in which the measuring electrodes 4 are arranged is narrower (smaller) and the molecular memory input channel 31 and the molecular memory measurement channel 32 are connected via the first taper channel 33.

As described above, a narrower width of the molecular memory measurement channel 32 is preferable in order to reduce noise due to the voltage for electrophoresis. When the width of the connection portion between the first taper channel 33 and the molecular memory measurement channel 32 is defined as W1, W1 may can be 200 nm or less, 180 nm or less, 160 nm or less, 140 nm or less, 120 nm or less, 100 nm or less, 90 nm or less, 80 nm or less, 70 nm or less, 60 nm or less, or 50 nm or less. On the other hand, the lower limit of W1 is not particularly limited as far as production thereof is possible. The lower limit can be, for example, but is not limited to, 20 nm or greater, 25 nm or greater, or 30 nm or greater.

The width of the molecular memory measurement channel 32 may be the same for the entire part or may be different as far as it does not affect analysis of a measurement result or the like. In the example illustrated in FIG. 5A, when the width at the end opposite to the width W1 of the molecular memory measurement channel 32 is defined as W1a, W1a may be the same as W1 or may be larger than or smaller than W1.

The gap between the pair of measuring electrodes 4a and 4b (gap G, see FIG. 5B) is not particularly limited as far as it enables measurement of tunnel current occurring when a molecular memory passes therebetween. The gap can be, for example, but is not limited to, 0.1 nm or greater, 0.3 nm or greater, 0.5 nm or greater, 0.7 nm or greater, or 0.9 nm or greater. On the other hand, the upper limit of the gap G can be, for example, but is not limited to, 50 nm or less, 30 nm or less, 10 nm or less, 8 nm or less, 6 nm or less, 5 nm or less, 4 nm or less, 3 nm or less, 2 nm or less, or 1 nm or less.

The length of the measuring electrode 4 (the length of gap G in the same direction as L2 of FIG. 5A) is also not particularly limited as far as tunnel current can be measured when a molecular memory passes therebetween. The length can be, for example, but is not limited to, 1000 nm or less, 800 nm or less, 600 nm or less, 400 nm or less, 200 nm or less, 100 nm or less, 80 nm or less, or 60 nm or less.

Note that, in the MCBJ, a smaller amount of deposition of the measuring electrode 4 (in a direction orthogonal to the longitudinal direction of the measuring electrode 4 or the direction H in FIG. 5B, hereafter, which may be referred to as “thickness”) is preferable in order to facilitate cutting. An increased thickness of the measuring electrode 4 may make it difficult to control a cutting location and may result in a rough sectional surface of the fabricated gap G. Thus, the thickness of the measuring electrode 4 can be, for example, but is not limited to, 80 nm or less, 70 nm or less, 60 nm or less, or 50 nm or less. The lower limit value of the thickness of the measuring electrode 4 is not particularly limited as long as tunnel current can be measured, and the lower limit value can be, for example, but is not limited to, 2 nm or greater, 4 nm or greater, 6 nm or greater, 8 nm or greater, 10 nm or greater, 15 nm or greater, or 20 nm or greater.

As described above, for reducing the thickness of the measuring electrode 4 to form the gap G by the MCBJ, it is preferable that the length of the measuring electrode 4 be greater than the thickness thereof. For example, the ratio of length/thickness may be, but is not limited to, 10 to 100.

The length L2 of the molecular memory measurement channel 32 is not particularly limited as far as it enables measurement of tunnel current occurring when a molecular memory passes through. An excessively large length L2 results in a longer entire channel of the measurement portion. In contrast, an excessively small length L2 makes it difficult to maintain the state where the elongated molecular memory is extended. Although not limited to, L2 can be 20 nm or greater, 25 nm or greater, 30 nm or greater, 35 nm or greater, 40 nm or greater, 45 nm or greater, or 50 nm or greater. Further, L2 can be 2000 nm or less, 1500 nm or less, 1000 nm or less, 800 nm or less, 600 nm or less, 400 nm or less, 200 nm or less, 180 nm or less, 160 nm or less, 140 nm or less, 120 nm or less, or 100 nm or less. It is naturally required that the length L2 be longer than the length of the gap G part of the measuring electrode 4.

To reduce noise due to the voltage for electrophoresis, a smaller depth H of the channel 3 is also preferable. The depth H of the channel 3 can be, for example, but is not limited to, 200 nm or less, 180 nm or less, 160 nm or less, 140 nm or less, 120 nm or less, 100 nm or less, 90 nm or less, 80 nm or less, 70 nm or less, 60 nm or less, or 50 nm or less. On the other hand, the depth H of the channel 3 can be, for example, 20 nm or greater, 25 nm or greater, or 30 nm or greater.

In the measurement portion illustrated in FIG. 5A to FIG. 5C, the length of the first taper channel 33 (L1 in FIG. 5A) and the width of the molecular memory input channel 31 (the portion connected to the first taper channel 33, W2 in FIG. 5A) are not particularly limited, and it is desirable that the width of the channel 3 be as small as possible. Note that, to input a solution containing molecular memories, the molecular memory input channel 31 may have a wider portion whose width is wider than W2, if necessary.

In the measurement portion, the width of the molecular memory collection channel 34 and the length of the second taper channel 35 (Lla in FIG. 5A), which is optionally and additionally provided, are not particularly limited, and it is desirable that the width of the channel 3 be as small as possible. Note that, to collect molecular memories, the molecular memory collection channel 34 may have a wider portion whose width is wider than W2a, if necessary.

In the measurement portion, when the width of the connection portion between the first taper channel 33 and the molecular memory measurement channel 32 is defined as W1 and the width of the connection portion between the first taper channel 33 and the molecular memory input channel 31 is defined as W2, the lower limit of W2/W1 may be 2 or greater, 3 or greater, 4 or greater, 5 or greater, 6 or greater, 7 or greater, 8 or greater, 9 or greater, or 10 or greater, and the upper limit thereof may be 50 or less, 40 or less, 30 or less, or 20 or less. Further, when the width of the connection portion between the first taper channel 33 and the molecular memory measurement channel 32 is defined as W1, and the length of the connection portion between the first taper channel and the molecular memory input channel is defined as L1, the lower limit of L1/W2 may be 0.3 or greater, 0.4 or greater, or 0.5 or greater, and the upper limit thereof may be 10 or less, 9 or less, 8 or less, 7 or less, 6 or less, or 5 or less.

When the shape of the first taper channel 33 has the ratio described above, the following advantageous effects are achieved.
(1) With the first taper channel 33 having the ratio described above, molecular memories in a solution can be easily straightened.
(2) While an electro-osmosis flow (EOF) occurs in the channel when the channel is filled with a solvent and a voltage is applied thereto, a backward flow occurs in a region along the wall. With the shape of the first taper channel 33 being formed within the range described above, occurrence of the EOF is likely to be suppressed, and an acceleration effect caused by electric field enhancement is obtained due to the shape of the first taper channel 33. This makes it easier to straighten molecular memories contained in the solution and then introduce the straightened molecular memories to the molecular memory measurement channel 32.

The measurement portion may include the second taper channel 35 arranged between the molecular memory measurement channel 32 and the molecular memory collection channel 34 and having an increasing channel width from the molecular memory measurement channel 32 to the molecular memory collection channel 34.

When the measurement portion includes the second taper channel 35, this prevents molecular memories from getting stuck at the exit of the molecular memory measurement channel 32 and achieves an advantageous effect of facilitating passage of the molecular memories.

When the width of the connection portion between the molecular memory measurement channel 32 and the second taper channel 35 is defined as W1a, the width of the connection portion between the second taper channel 35 and the molecular memory collection channel 34 is defined as W2a, and the length of the connection portion between the second taper channel 35 and the molecular memory measurement channel 32 and the connection portion between the second taper channel 35 and the molecular memory collection channel 34 is defined as Lla, the measurement portion may satisfy the relationship of W1=W1a, W2=W2a, and L1=L1a. In other words, the channel 3 may be formed so as to be symmetrical laterally with respect to the molecular memory measurement channel 32 as the center.

The analysis unit 9 determines the direction of molecular memories passing between the measuring electrodes 4 based on the conductance of molecules constituting the address region 101 (101a, 101b) and the conductance of molecules constituting the memory region 102. Further, the analysis unit 9 determines the direction of molecular memories passing between the measuring electrodes based on the conductance of molecules constituting the first address region 101a and the conductance of molecules constituting the second address region 101b. Each molecular memory has an elongated shape and passes between the measuring electrodes 4 while being extended. Thus, the direction of molecular memories passing between the measuring electrodes 4 is not constant. In other words, in the case of the molecular memory 100 illustrated in FIG. 1, a case where decoding is started from the address region 101 and a case where decoding is started from the memory region 102 are mixed. Similarly, in the case of the molecular memory 100a illustrated in FIG. 2, a case where decoding is started from the first address region 101a and a case where decoding is started from the second address region 101b are mixed. Because the analysis unit 9 determines the passage direction of the molecular memories, information stored in the molecular memories can be correctly decoded.

### [Embodiment of Decoding Method of Molecular Memory]

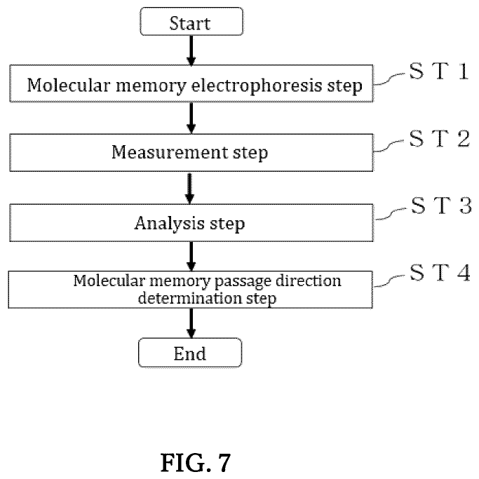

Next, an embodiment of a decoding method of a molecular memory will be described with reference to FIG. 7 (hereafter, which may be simply referred to as “decoding method”). FIG. 7 is a flowchart illustrating an example of the decoding method. The decoding method is performed by using the device 1 described above. Further, as the molecular memory, the molecular memory 100, 100a, 100′, or 100a′ described above or a molecular memory modified within the scope of the technical concept disclosed in the present application can be used. Note that, to avoid complication, the references of the molecular memory will be omitted in the following description.

The decoding method includes a molecular memory electrophoresis step (ST1), a measurement step (ST2), an analysis step (ST3), and a molecular memory passage direction determination step (ST4).

The molecular memory electrophoresis step (ST1) applies a voltage across the molecular memory input channel 31 and the molecular memory collection channel 34 to electrophorese molecular memories in the molecular memory input channel 31 toward the molecular memory collection channel 34. More specifically, this step is performed by inputting a solution containing molecular memories in the molecular memory input channel 31, inputting a solvent to the molecular memory collection channel 34, and applying a voltage across the first electrode 61 and the second electrode 62. In the first taper channel 33, the molecular memory measurement channel 32, and the second taper channel 35 formed if necessary, fluid communication is formed by permeation of the input molecular memories or the input solvent due to capillary force. The solvent used for preparing a solution containing molecular memories may be any solvent as long as it is electroconductive. The solvent may be, for example, but is not limited to, ultrapure water, a buffer solution, or the like. For example, the ultrapure water can be produced by using Milli-Q (registered trademark) Integral 3 (device name) manufactured by EMD Millipore (Milli-Q (registered trademark) Integral 33/5/1015 (catalog number)). The buffer solution may be a known electrophoresis buffer such as a TE buffer, a TBE buffer, or the like. The concentration of the buffer can be adjusted as appropriate within a range where electrophoresis is possible, for example, such as 1 μM or lower, but is not limited thereto. Further, to reduce an impact of an electro-osmosis flow (EOF), an amphiphilic chemical substance as well as a surfactant such as polyvinyl-pyrrolidone (PVP) may be added to the solution containing molecular memories if necessary.

In the example illustrated in FIG. 4, the measurement part is formed of the molecular memory measurement channel 32 and the pair of measuring electrodes 4a, 4b arranged in the molecular memory measurement channel 32. Further, the electrophoresis first electrode (hereafter, which may be referred to as “first electrode”) 61 is formed at a part in contact with the solution containing molecular memories in the molecular memory input channel 31, and the electrophoresis second electrode (hereafter, which may be referred to as “second electrode”) 62 is formed at a part in contact with the solvent in the molecular memory collection channel 34. Further, a first power supply 6a connected to the first electrode 61 and a first power supply 6b connected to the second electrode 62 are used to apply voltages interposing the measuring electrodes 4a, 4b therebetween, and thereby molecular memories are electrophoresed and pass between the measuring electrodes 4a, 4b. Note that, although FIG. 4 illustrates the example in which two first power supplies 6 are used to apply an electrophoresis voltage, a single first power supply 6 may be used.

The first electrode 61 and the second electrode 62 can be formed of a known electroconductive metal such as Ag/AgCl, aluminum, copper, platinum, gold, silver, titanium, or the like. The first electrode 61 and the second electrode 62 may be formed on the base member 2 or may be inserted via a hole in the cover member 5 as a separate member from the device 1.

An excessively small voltage applied by the first power supply 6 will reduce the motion speed of the molecular memories and requires a long time for measurement. The voltage can be, for example, but is not limited to, 10 mV or higher, 15 mV or higher, 20 mV or higher, 25 mV or higher, or 30 mV or higher. On the other hand, the upper limit of the voltage applied by the first power supply 6 can be set as appropriate under consideration on the accuracy in the analysis step described later, the width of the channel 3, and the like. The voltage can be, for example, but is not limited to, 5 V or lower, 3 V or lower, 1 V or lower, 500 mV or lower, 300 mV or lower, 100 mV or lower, 90 mV or lower, 80 mV or lower, 70 mV or lower, 60 mV or lower, or 50 mV or lower.

In the measurement step (ST2), tunnel current occurring when molecular memories pass through the gap between the pair of measuring electrodes 4a and 4b arranged in the molecular memory measurement channel 32 is measured. In the example illustrated in FIG. 4, in the measurement step (ST2), a voltage is applied across the pair of measuring electrodes 4a and 4b by the tunnel current measuring power supply (hereafter, which may be referred to as “second power supply”) 8, and a change in the tunnel current occurring when the molecular memories pass through the gap between the pair of measuring electrodes 4a and 4b is measured by the tunnel current detection unit 7. Note that the example illustrated in FIG. 4 represents an example of the measurement step (ST2), and the measurement step is not limited thereto. Since a change in the generated tunnel current is at a picoampere level, a known ammeter that can measure current at a picoampere level can be used for the tunnel current detection unit 7. Further, a current value may be calculated from a voltage measured by a voltmeter. The tunnel current detection unit 7 may optionally and additionally include a current amplifier, a noise removal device, an analog-to-digital (A/D) converter, or the like. When the tunnel current detection unit 7 includes a current amplifier, a noise removal device, an A/D converter, or the like, data that is more convenient for analysis can be provided instead of raw data of measured tunnel current values. Alternatively, the tunnel current detection unit 7 may include only the configuration that can measure a change in tunnel current, and the analysis unit 9 may include a current amplifier, a noise removal device, an A/D converter, or the like.

The second power supply 8 applies a voltage across the pair of measuring electrodes 4a and 4b. The voltage applied by the second power supply 8 is not particularly limited as long as it enables measurement of tunnel current. For example, although not limited to, the lower limit of said voltage can be 20 mV or higher, 50 mV or higher, or 100 mV or higher, and the upper limit thereof can be 750 mV or lower, 500 mV or lower, 250 mV or lower, or the like. The specific configuration of the second power supply 8 is not particularly limited, and a known power supply device can be used. In the example illustrated in FIG. 4, in the device 1, it is possible to reduce the voltage required to electrophoresis of molecular memories by significantly reducing the width of the channel 3, in particular, the molecular memory measurement channel 32. Thus, the tunnel current detection unit 7 can acquire tunnel current measurement values with small noise components in measuring the tunnel current occurring when molecular memories pass through the gap between the measuring electrodes 4. In the tunnel current measurement step, tunnel current can be measured for each molecule constituting a molecular memory when the molecular memory passes through the gap between the pair of measuring electrodes 4a and 4b.

In the analysis step (ST3), the molecular sequence constituting a molecular memory is analyzed from a measurement result on the measured tunnel current. In the example illustrated in FIG. 4, the analysis step (ST3) is performed by the analysis unit 9 (hereafter, the analysis step performed by the analysis unit may be simply referred to as “analysis unit”). More specifically, the analysis unit 9 calculates the conductance from a tunnel current measurement value. The conductance can be calculated by dividing a tunnel current measurement value by a voltage applied across the pair of measuring electrodes 4a and 4b. The conductance calculated from tunnel current occurring when a molecule passes between the pair of measuring electrodes 4a and 4b varies in accordance with the type of the molecule. This is because how the current easily flows differs in accordance with a difference in the base structure a molecule when the molecule is a nucleoside or a difference in the construction structure of a molecule when the molecule is an amino acid, for example. Therefore, a measured conductance value of the molecule is compared to conductance values of various molecules measured and calculated in advance, the tunnel current measurement value is analyzed in a time-series manner, and thereby the molecular sequence constituting the molecular memory can be read. Note that the above description represents a mere example of the analysis unit 9. As long as the molecular sequence can be analyzed from measured tunnel current, a method other than the method using conductance may be used for analysis. Note that the conductance is an absolute value obtained from measured data and thus is a value including noise or fluctuation of a measuring system. Normalization by using guanine conductance (Relative G) may be applied to reduce the impact of noise or the like of the system, if necessary.

In the molecular memory passage direction determination step (ST4), the direction of the molecular memory passing between the measuring electrodes 4a, 4b is determined based on the conductance of molecules constituting the (first, second) address region 101 and the conductance of molecules constituting the memory region 102. The molecular memory 100, 100a disclosed in the present application is designed such that at least some of the molecules constituting the (first, second) address region 101 and the memory region 102 differ in types from each other. Therefore, the direction from which of the address region 101 or the memory region 102 the decoding was started in the case of the molecular memory 100 as well as the direction from which of the first address region 101a or the second address region 101b the decoding was started in the case of the molecular memory 100a can be determined based on the conductance in accordance with types of molecules.

The decoding method may optionally and additionally include an information recovery step after the molecular memory passage direction determination step (ST4). For example, a molecular sequence table corresponding to the ASCII code table may be prepared, and encoded information may be recovered by using this molecular sequence table.

Further, as illustrated in FIG. 4, an example of the device for performing the decoding method may include the display unit 10 for displaying information provided in the analysis step (ST3) or the passage direction determination step (ST4), the program memory 11 storing a program in advance that causes the analysis unit 9 and the display unit 10 to function, and the control unit 12 for reading and executing the program stored in the program memory 11. The program may be stored in the program memory 11 in advance or may be stored in a storage medium and then stored in the program memory 11 with the use of some installing technology.

As the display unit 10, a known display device such as a liquid crystal display, a plasma display, or an organic EL display can be used.

### INDUSTRIAL APPLICABILITY

With the use of the molecular memory, the production method of a molecular memory, the decoding method of a molecular memory, and the device for decoding a molecular memory disclosed in the present application, a large capacity molecular memory can be provided. Therefore, the molecular memory, the production method of a molecular memory, the decoding method of a molecular memory, and the device for decoding a molecular memory disclosed in the present application are useful in the information industry.

### LIST OF REFERENCE SYMBOLS

1 device
2 base member
2a substrate
2b insulating layer
2c deposition layer
2d resist layer
3 channel
31 molecular memory input channel
32 molecular memory measurement channel
33 first taper channel
34 molecular memory collection channel
35 second taper channel
4, 4a, 4b measuring electrode
5 cover member
6, 6a, 6b electrophoresis power supply
61 electrophoresing first electrode
62 electrophoresis second electrode
7 tunnel current detection unit
8 tunnel current measuring power supply
9 analysis unit
10 display unit
11 program memory
12 control unit
100 molecular memory
101 address region
101a first address region
101b second address region
102 memory region
103, 103a, 103b redundant region

1. A molecular memory comprising: an address region; and a memory region connected to the address region,
wherein the address region and the memory region are constituted of molecules that generate tunnel current,
wherein the memory region is constituted of four or more types of molecules selected from a first molecule group,
wherein the address region is constituted of four or more types of molecules selected from a second molecule group,
wherein the molecules included in the first molecule group
all are of different types from the types of the molecules included in the second molecule group, or
include the same type as and a different type from the types of the molecules included in the second molecule group, and
wherein due to the molecules included in the first molecule group, at least some of the molecules constituting the address region and the memory region differ in types.

2. The molecular memory according to claim 1, wherein when the first molecule group includes molecule of the same type as the molecules included in the second molecule group, the molecule of the same type included in the first molecule group and the second molecule group is not arranged neither at a terminal on the memory region side in the address region nor at a terminal on the address region side in the memory region.

3. The molecular memory according to claim 1,
wherein a molecule having the smallest conductance in the molecules included in the first molecule group is not arranged at a terminal of the memory region on the opposite side from the address region side, and
wherein a molecule having the smallest conductance in the molecules included in the second molecule group is not arranged at a terminal of the address region on the opposite side from the memory region side.

4. The molecular memory according to claim 1, wherein all the types of the molecules included in the first molecule group differ from the types of the molecules included in the second molecule group.

5. The molecular memory according to claim 3, wherein all the types of the molecules included in the first molecule group differ from the types of the molecules included in the second molecule group.

6. The molecular memory according to claim 4,
wherein one of the first molecule group and the second molecule group includes four or more types of molecules selected from a group consisting of: 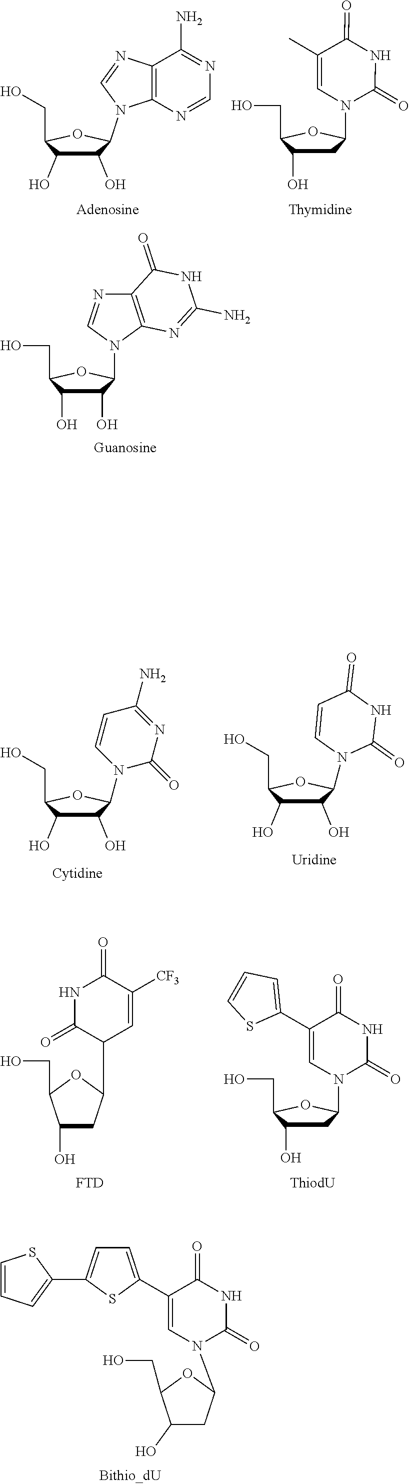 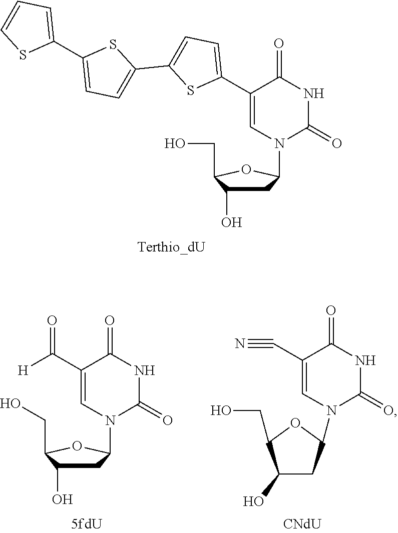
and
wherein the other of the first molecule group and the second molecule group includes four or more types of molecules selected from a group consisting of:

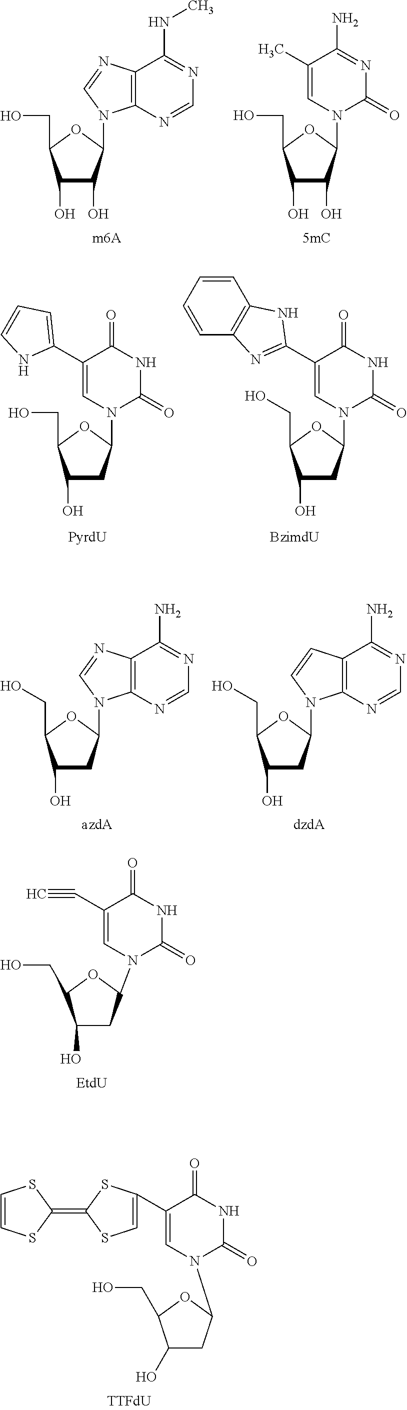

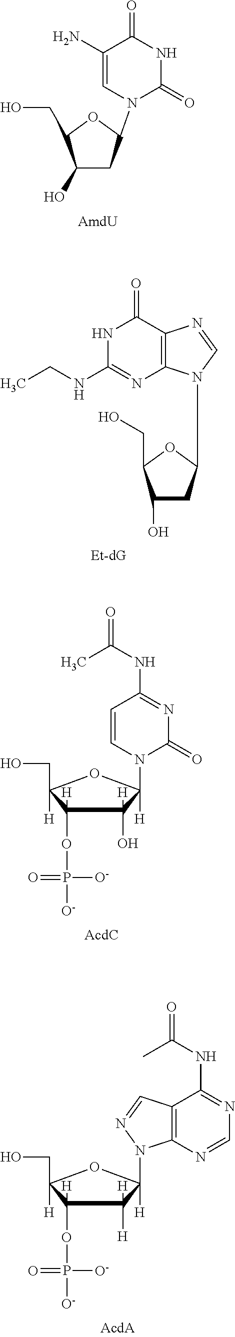

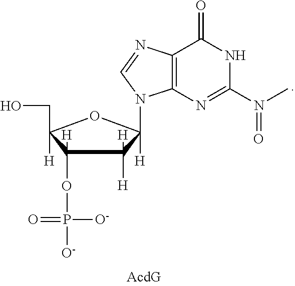

7. The molecular memory according to claim 1, wherein a first conductance range and a second conductance range do not overlap each other, the first conductance range being a range from the minimum value to the maximum value of conductance of the molecules included in the first molecule group, and the second conductance range being a range from the minimum value to the maximum value of conductance of the molecules included in the second molecule group.

8. The molecular memory according to claim 6, wherein a first conductance range and a second conductance range do not overlap each other, the first conductance range being a range from the minimum value to the maximum value of conductance of the molecules included in the first molecule group, and the second conductance range being a range from the minimum value to the maximum value of conductance of the molecules included in the second molecule group.

9. The molecular memory according to claim 1,
wherein the address region includes
a first address region connected to one end of the memory region, and
a second address region connected to the other end of the memory region,
wherein the first address region is constituted of four or more types of molecules selected from a second-a molecule group,
wherein the second address region is constituted of four or more types of molecules selected from a second-b molecule group,
wherein the molecules included in the first molecule group
all are of different types from the types of the molecules included in the second-a molecule group, or
include the same type as and a different type from the types of the molecules included in the second-a molecule group, and
all are of different types from the types of the molecules included in the second-b molecule group, or
include the same type as and a different type from the types of the molecules included in the second-b molecule group, and
wherein the molecules included in the second-b molecule group
all are of different types from the types of the molecules included in the second-a molecule group, or
include the same type as and a different type from the types of the molecules included in the second-a molecule group.

10. The molecular memory according to claim 9,
wherein the types of the molecules included in the first molecule group, the types of the molecules included in the second-a molecule group, the types of the molecules included in the second-b molecule group all differ from each other,
wherein one of the second-a molecule group and the second-b molecule group includes four or more types of molecules selected from a group consisting of: 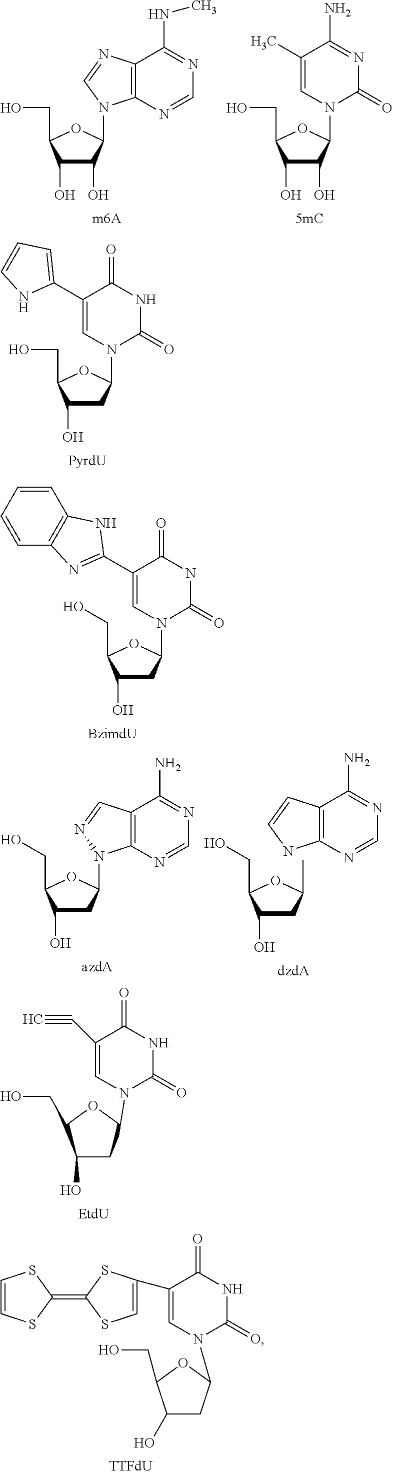
and
wherein the other of the second-a molecule group and the second-b molecule group includes four or more types of molecules selected from a group consisting of:

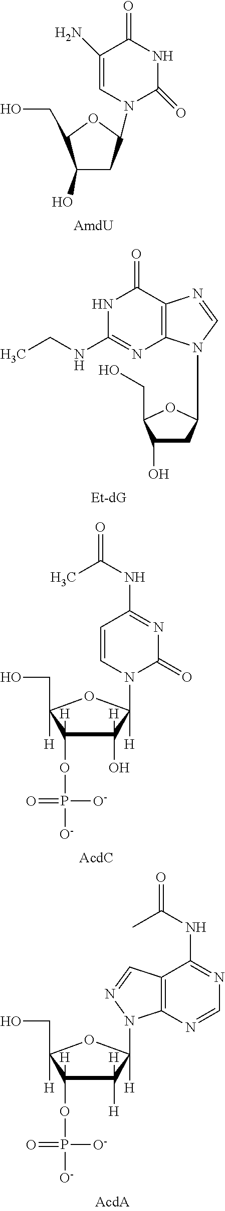

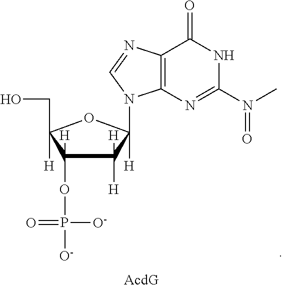

11. The molecular memory according to claim 1,
wherein a redundant region is connected between the address region and the memory region, and
wherein the redundant region is constituted of a redundant region molecule that generates tunnel current, and the conductance of the redundant region molecule is smaller than the conductance of molecules constituting the address region and the memory region.

12. The molecular memory according to claim 9,
wherein a first redundant region is connected between the first address region and the memory region,
wherein a second redundant region is connected between the second address region and the memory region, and
wherein the first redundant region and the second redundant region are constituted of redundant region molecules that generate tunnel current, and the conductance of the redundant region molecules is smaller than the conductance of molecules constituting the first address region, the second address region, and the memory region.

13. A production method of the molecular memory according to claim 1, the production method comprising:
an information preparation step of preparing information to be encoded;
a molecular sequencing step of converting the prepared information into molecules constituting a molecular memory to determine a sequence of the molecular memory; and
a synthesis step of synthesizing molecules constituting the molecular memory based on the determined sequence.

14. A device for decoding the molecular memory according to claim 1, the device comprising:
a base member;
a channel formed in the base member;
a pair of measuring electrodes used for measuring tunnel current occurring when the molecular memory passes between the measuring electrodes; and
an analysis unit,
wherein the channel includes
a molecular memory input channel,
a molecular memory measurement channel in which the measuring electrodes are arranged,
a first taper channel arranged between the molecular memory input channel and the molecular memory measurement channel and having a decreasing channel width from the molecular memory input channel to the molecular memory measurement channel, and
a molecular memory collection channel used for collecting the molecular memory that passed through the molecular memory measurement channel,
wherein the width of a connection portion between the first taper channel and the molecular memory measurement channel is 20 nm to 200 nm, and
wherein the analysis unit is configured to
determine the direction of the molecular memory passing between the measuring electrodes based on the conductance of molecules constituting the address region and the conductance of molecules constituting the memory region, or
determine the direction of the molecular memory passing between the measuring electrodes based on the conductance of molecules constituting the first address region and the conductance of molecules constituting the second address region.

15. A decoding method of a molecular memory using the device according to claim 14,
wherein the molecular memory comprising: an address region; and a memory region connected to the address region,
wherein the address region and the memory region are constituted of molecules that generate tunnel current,
wherein the memory region is constituted of four or more types of molecules selected from a first molecule group,
wherein the address region is constituted of four or more types of molecules selected from a second molecule group,
wherein the molecules included in the first molecule group
all are of different types from the types of the molecules included in the second molecule group, or
include the same type as and a different type from the types of the molecules included in the second molecule group, and
wherein due to the molecules included in the first molecule group, at least some of the molecules constituting the address region and the memory region differ in types;
the decoding method comprising: a molecular memory electrophoresis step; a measurement step; an analysis step; and a molecular memory passage direction determination step,
wherein the molecular memory electrophoresis step applies a voltage across the molecular memory input channel and the molecular memory collection channel to electrophorese a molecular memory in the molecular memory input channel toward the molecular memory collection channel,
wherein the measurement step measures tunnel current occurring when the molecular memory passes through a gap between the pair of measuring electrodes arranged in the molecular memory measurement channel,
wherein the analysis step analyzes a sequence of molecules constituting the molecular memory from a measurement result of the measured tunnel current, and
wherein molecular memory passage direction determination step
determines the direction of the molecular memory passing between the measuring electrodes based on the conductance of molecules constituting the address region and the conductance of molecules constituting the memory region, or
determines the direction of the molecular memory passing between the measuring electrodes based on the conductance of molecules constituting the first address region and the conductance of molecules constituting the second address region.

16. A production method of the molecular memory according to claim 2, the production method comprising:
an information preparation step of preparing information to be encoded;
a molecular sequencing step of converting the prepared information into molecules constituting a molecular memory to determine a sequence of the molecular memory; and
a synthesis step of synthesizing molecules constituting the molecular memory based on the determined sequence.

17. A production method of the molecular memory according to claim 3, the production method comprising:
an information preparation step of preparing information to be encoded;
a molecular sequencing step of converting the prepared information into molecules constituting a molecular memory to determine a sequence of the molecular memory; and
a synthesis step of synthesizing molecules constituting the molecular memory based on the determined sequence.

18. A production method of the molecular memory according to claim 4, the production method comprising:
an information preparation step of preparing information to be encoded;
a molecular sequencing step of converting the prepared information into molecules constituting a molecular memory to determine a sequence of the molecular memory; and
a synthesis step of synthesizing molecules constituting the molecular memory based on the determined sequence.

19. A production method of the molecular memory according to claim 5, the production method comprising:
an information preparation step of preparing information to be encoded;
a molecular sequencing step of converting the prepared information into molecules constituting a molecular memory to determine a sequence of the molecular memory; and
a synthesis step of synthesizing molecules constituting the molecular memory based on the determined sequence.

20. A production method of the molecular memory according to claim 6, the production method comprising:
an information preparation step of preparing information to be encoded;
a molecular sequencing step of converting the prepared information into molecules constituting a molecular memory to determine a sequence of the molecular memory; and
a synthesis step of synthesizing molecules constituting the molecular memory based on the determined sequence.
